(19) United States
(12) Patent Application Publication
(10) Pub. No.: US 2025/0361610 A1
(43) Pub. Date: Nov. 27, 2025

(54) ATOMIC LAYER DEPOSITION OF SUPERCONDUCTING TRANSITION METAL NITRIDES FOR QUANTUM CIRCUITS AND DETECTORS

(71) Applicant: California Institute of Technology, Pasadena, CA (US)

(72) Inventors: John Femi-Oyetoro, Pasadena, CA (US); Harold Frank Greer, Los Angeles, CA (US)

(73) Assignee: California Institute of Technology, Pasadena, CA (US)

(21) Appl. No.: 18/793,344

(22) Filed: Aug. 2, 2024

Related U.S. Application Data
(60) Provisional application No. 63/530,426, filed on Aug. 2, 2023.
(60) Provisional application No. 63/550,398, filed on Feb. 6, 2024.

(51) Int. Cl. C23C 16/455; C23C 16/34; H01B 12/00; H01B 13/00

(52) U.S. Cl. CPC C23C 16/45527; C23C 16/34; C23C 16/45542; C23C 16/45553; H01B 12/00; H01B 13/003; H01J 2237/0473; H01J 2237/332

(57) ABSTRACT

A method and system for depositing a transition nitride film including depositing the film on a substrate using plasma enhanced atomic layer deposition and using a number of deposition cycles in an atmosphere comprising no hydrogen or less than 1% hydrogen. A film and device comprising the transition metal nitride is further disclosed.

### CROSS-REFERENCE TO RELATED APPLICATIONS

This application claims the benefit under 35 U.S.C. Section 119 (e) of the following co-pending and commonly-assigned U.S. Provisional Patent Applications:

Ser. No. 63/530,426 filed Aug. 2, 2023 entitled “Atomic Layer Deposition of Superconducting Transition Metal Nitrides for Quantum Circuits and Detectors” (CIT-9052) by John Femi-Oyetoro and Harold Frank Greer; and

Ser. No. 63/550,398 filed Feb. 6, 2024 entitled “Atomic Layer Deposition of Superconducting Transition Metal Nitrides for Quantum Circuits and Detectors” (CIT 9052-P2) by John Femi-Oyetoro and Harold Frank Greer;
both of which applications are incorporated by reference herein.

### FEDERALLY SPONSORED RESEARCH AND DEVELOPMENT

This invention was made with government support under Grant No. 80NMO0018D0004 awarded by NASA (JPL). The government has certain rights in the invention

### BACKGROUND OF THE INVENTION

Transition metal nitrides, such as TiN, NbN, and NbTiN, possess a high intrinsic kinetic inductance (KI) due to their substantial London penetration depth. This characteristic is crucial in numerous superconducting devices (SDs) utilized across various research fields and technologies, including quantum processors, ² extendedlifetime quantum transduction, ³ highly sensitive photon detection ^{4,5} and spectroscopy, ⁶ and quantum-limited parametric amplification. ^{5,7}

Traditionally, superconducting films are deposited using reactive sputtering. However, atomic layer deposition (ALD) technique offers significant advantages compared to this method. ALD provides precise control over film thickness at the atomic level, resulting in exceptional uniformity and conformality, even on complex three-dimensional (3D) structures. It also mitigates issues related to pinholes and shadowing effects commonly associated with sputtering. When grown with minimal impurities, ALD serves as a reliable alternative to scarce and high-quality sputtering targets.

Furthermore, the KI of these superconducting film scales inversely to its thickness. This highlights the critical importance of controlling and achieving a thin-film configuration with uniformity over a large area and high aspect ratios, especially for large arrays requiring consistent superconducting properties and high yield applications. ALD emerges as a viable approach for fabricating these SDs, offering precise control over film thickness, uniformity, and homogeneity over large areas which is particularly critical for fabricating large-scale devices or detector arrays and obtaining higher yields for fully functional devices per wafer.

However, the attainment of high-quality superconducting films via ALD poses significant challenges. The present invention satisfies this need.

### SUMMARY OF THE INVENTION

The present disclosure describes a robust and repeatable ALD process that yields good superconducting parameters with minimal impurities, which can be used to ensure the effective utilization of high-performance SDs compatible with ALD techniques.

As an illustrative example, the present disclosure examines the superconducting properties of titanium nitride (TiN) deposited via plasma-enhanced atomic layer deposition (PEALD) on both planar and three-dimensional (3D) structures. Our deposition method achieves consistent uniformity, maintaining sheet resistance (R_{□})>95% across a 6-inch wafer, crucial for large-scale superconducting device fabrication and yield optimization. The planar films, akin to reactive-sputtered TiN, reached a critical temperature (T_{c}) of 4.35 K at a thickness of ≈40 nm. For aspect ratios (ARs) between 2 and 40, we observed a single transition of ≈2 K at ARs between 2 and 10.5, and multiple transitions at ARs >10.5.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIG. 1. Flowchart illustrating a method of depositing a transition metal nitride film.

FIG. 2 Plasma Enhanced Atomic Layer Deposition (PEALD) apparatus according to one or more embodiments described herein.

FIGS. 3A-3C. Film properties of a TiN film deposited according to PEALD as described herein, wherein FIG. 3A plots resistance (R per square) as a function of temperature. FIG. 3B plots thickness variation across a surface of the wafer, showing repeatability and uniformity over a 6-inch wafer with standard deviation of 0.77, and thickness uniformity of 98.7%, and FIG. 3C plots thickness and resistivity as a function of bias power applied during PEALD.

FIG. 4A. SIMS spectra reveal contamination and composition profiles, displaying atomic concentrations of H, C, O, N, and Ti in an 80 nm PEALD TiN film. The TiN number density (1023 atoms/cc) serves as the basis for conversion to atom % units.

FIG. 4B. A grazing incidence XRD scan identifies the phase, with the inset showing the preferential (111) orientation at 2θ=36.5° of an 80 nm PEALD TiN film.

FIG. 4C. Resistance versus temperature on 40 nm PEALD and sputtered TiN films demonstrates T_{c} values of 4.35 K and 4.0 K, respectively.

FIG. 5A shows a bright-field (BF) HRTEM image with smaller grains below the blue dashed lines preceding larger grains above.

FIG. 5B. High-angle annular dark-field STEM image highlighting multilayered grain boundaries.

FIGS. 5C-5F. EELS map for C, N, Ti, and N, revealing a SiN, interfacial layer in FIGS. 5C and 5E, or a gap in the Ti signal in FIG. 5F, wherein FIG. 5D shows the map for C, FIG. 5E shows the nitrogen, and FIG. 5F shows the titanium.

FIG. 5G displays EDS map detecting minimal oxygen content in an 80 nm PEALD TiN film.

FIGS. 6A-6C. SEM images of highly conformal PEALD TiN in FIG. 6a-6b correspond to red circles in Trenches 1 and 9 in FIG. 6C, featuring aspect ratios of 2 to 40 after deep reactive ion etching (DRIE).

FIG. 6D. BF HRTEM image of Trench 9's flat, top corner, and sidewall, representing a highly conformal film. The inset shows a magnified top corner with visible residual oxide.

FIG. 6E. High-magnification BF HRTEM image of Trench 9's sidewall, revealing elongated, misaligned grains at the top.

FIG. 6F. A high-magnification BF HRTEM image at the bottom of Trench 9 reveals a pronounced underlying oxide.

FIG. 6G. High magnification BF HRTEM image of Trench 9's bottom corner shows residual oxide and a thinner TiN film, taken at the red box in the inset.

FIGS. 6H and 6I show EDS maps of Ti (blue), N (green), O (orange), and Si (purple) for FIGS. 6D and 6F respectively. trenches with PEALD TiN post-DRIE. FIGS. 6D and 6I focus on Trench 9, which has the highest AR of 40. In FIGS. 6D and 6E, the BF HRTEM image shows a film with a smooth texture and a rough morphology at the top corner, and rougher than Trenches 1 and 7 (FIG. 16). Notably, an oxide layer is visible, concentrated at the top corners, consistent with features observed in the significant corners of Trenches 1 and 7 (FIG. 16). The films along the sidewalls in FIG. 6E exhibit a slightly rougher texture and randomly oriented grains compared to the top surface in FIG. 5D and FIG. 16A of Trench 9. A significantly thick oxide layer at the base in FIG. 6F and bottom corner of FIG. 6G shows the impact of high AR and the inability of the post HF-treatment to completely remove the oxide within the necessary timeframe. In contrast, Trenches 1 and 7 did not experience this issue (FIG. 16). Stress distribution resulting from the underlying oxide could potentially lead to different superconducting properties. EDS maps in FIGS. 6h and 6i for 6d and 6f respectively show a well-balanced Ti/N mixture.

FIG. 7A Schematically outlines the laser trimming procedure for removing TiN from trench edges and lips. Trenches 1-9 are represented by black lines, with TiN shown in golden on the planar surface and within the trench. The grey area indicates TiN removal by laser ablation, revealing the Si substrate. Red pads denote positions for four-wire connections, and the dashed yellow line signifies the laser-cleaved region. The blue arrow, from i to ii, indicates enforced current flow within the trench due to electrical isolation by laser trimming and cleavage.

FIG. 7B. Resistance versus temperature plot highlights T for Trenches 1-9 and the region between Trenches 1 and 9 (All Trenches),

FIGS. 7C-7G with scaling from 700Ω. showcase morphological, grain orientation, and composition variations in the planar PEALD TiN film of Trench 9 in (FIG. 7C), top corner in (FIG. 7D), sidewalls in (FIG. 7E) and (FIG. 7F), and at the bottom in (FIG. 7G). Refer to supplementary section for detailed information on step coverage, morphology, and composition for Trenches 1,7, and 9

FIG. 8A. AFM of a 40 nm PEALD TiN film, with an RMS of 1 nm.

FIG. 8B. Sheet resistance versus bias voltage, showing an optimized temperature of 300° C. and an optimal bias voltage of 127 V.

FIG. 8C. High-resolution TEM of unbiased PEALD TiN in a trench exhibits different behavior compared to biased PEALD discussed in the manuscript, demonstrating no misaligned grains.

FIG. 9. Shows the XRR data comparing a 40 nm (blue) and 80 nm (green) PEALD TiN film.

FIGS. 10A-10B. Display the eddy current contactless sheet resistance of (FIG. 10A) reactively sputtered TiN (FIG. 10A) and PEALD TiN (FIG. 10B). The 103-point map was measured, excluding a 0.1-inch edge, across a 6-inch wafer. The uniformity levels are 81% for FIG. 10A and 95% for FIG. 10B.

FIG. 11. Shows the XRR data comparing a 40 nm (blue) and 80 nm (green) reactive sputtered TiN film.

FIGS. 12A-12D. XRD scan of the phase identification and a preferential (111) orientation of an 80 nm PEALD TiN film. The profile fitting for GI-XRD of all crystallite sizes not parallel to the sample surface in FIG. 12A (parameters tabulated in FIG. 12B) and symmetric XRD of all crystallite sizes parallel to the sample surface in FIG. 12C (parameters tabulated in FIG. 12D).

FIG. 13. SIMS spectra display contamination and composition profiles revealing the atomic concentration levels of H, C, O, N, and Ti within an 80 nm reactive sputtered TiN film.

FIG. 14. HRTEM image showing a Si underlying substrate, SiNₓ interfacial layer, and polycrystalline TiN.

FIG. 15. Resistance versus temperature measurements of 80 nm-thick PEALD and sputtered TiN films demonstrate T_{c} values of 4.5 K and 4.2 K, respectively, at a 50% reduction in Rₛ from its value at 5 K.

FIGS. 16A-16B show HAADF STEM images illustrating the step coverage of PEALD TiN in Trenches 1, 7, and 9. Showcasing (FIG. 16A) the top, (FIG. 16B) the sidewall, and (FIG. 16C) the bottom and

FIG. 16D shows a bright-field HRTEM image of the bottom corner. The circles in the inset in FIG. 16A indicate the approximate locations where the images were taken, with purple representing the top, yellow representing the sidewall, blue representing the bottom, and red representing the bottom corner.

FIGS. 17A-17C. EELS spectra for C, N, Ti, and N of PEALD in Trenches 1, 7, and 9 are presented, highlighting (FIG. 17A) the top corner, (FIG. 17B) the sidewall, and (FIG. 17C) the bottom. The spectra were acquired at the sample location indicated in the inset of FIG. 16A.

FIGS. 18A-18C illustrate flux directions. In FIG. 18A, the ion flux to the sidewall is significantly lower compared to the field and occurs at a glancing angle. In FIG. 18B the precursor flux endures through multiple bounces. In FIG. 18C, reactive radicals (N*) exhibit a cosine distribution in their behavior.

FIG. 19 illustrates a device comprising an interconnect.

FIG. 20 illustrates a kinetic inductance parametric amplifier (KIPA) whose transition metal nitride layers were deposited using the PEALD as described herein.

FIG. 21 is a schematic illustration of proposed Transition Edge Sensor (TES) whose superconducting layers (comprising transition metal nitride) could be deposited using PEALD as described herein.

FIG. 22 is a schematic of a proposed Quantum Processor whose superconducting layers (comprising transition metal nitride) could be be deposited using PEALD as described herein.

FIG. 23. Example Hardware environment.

FIG. 24. Example network environment.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized, and structural changes may be made without departing from the scope of the present invention.

### Technical Description

Significant efforts have been dedicated to utilizing ALD for the fabrication of SDs. Despite extensive investigations into ALD techniques, concerns persist regarding high process temperature, reliability, repeatability, reproducibility, and the attainment of high-quality films with minimal impurities. Elevated process temperatures can lead to the formation of amorphous interfacial layers between the TiN film and the underlying substrate, which in turn can introduce two-level systems (TLS). These TLS can result in a reduced internal quality factor and potentially limit device performance. Reproducibility issues may arise from variations in the tool, while repeatability issues can occur when the tool is shared among multiple users, potentially leading to contamination from other processes.

To address these concerns, our technology utilizes a lower deposition temperature and a reliable, repeatable ALD process. This approach has demonstrated the best superconducting parameters achieved to date, with respect to the aforementioned gas chemistries and the specific timing of the ion bombardment approach. To enhance the quality of the film, we employed Tetrakis (dimethylamido) titanium (TDMAT) as the precursor and a nitrogen/argon mixture for the plasma step for deposition of titanium nitride films. TDMAT presents several notable advantages, including enhanced reactivity resulting in higher growth per cycle (GPC) and reduced process temperatures. However, other precursors could be used, such as (tert-butylimido) tris(diethylamido)niobium(V) (TBTDEN) or (tert-butylimido) tris(methylethylamido)niobium(V) (TBTMEN) for the film comprising NbN, or Tetrakis(ethylmethylamido) vanadium for the film comprising VN. Other examples of precursors include the chlorides or fluorides of the transition metal being used to synthesize the transition metal nitride, e.g., TiCl₄, TiCl₅, VCl₄, VCl₅, NbCl₄, NbCl₅.

During the deposition process, low pressure conditions (<3 mTorr) were necessary during the plasma half-cycle, while the chamber pressure was maintained at approximately <220 mTorr during the TDMAT half-cycle.

Additionally, an ion bombardment intermittent step was incorporated by applying RF substrate biasing during the latter half of the plasma exposure. This technique serves to improve film densification, eliminate precursor residues, promote surface adatom diffusion, and enhance film quality. Maintaining low pressure is essential to minimize sputtering in inductively coupled plasma (ICP) tubes, with a more pronounced effect observed in quartz tubes compared to alumina tubes. These ion-induced erosion leads to oxygen contamination in conductive nitrides.

Ion bombardment has a significant influence on the growth, microstructure, and composition of thin films. These changes can be attributed to the enhanced mobility of adatoms, which occurs due to momentum transfer from bombarding ions, leading to film densification. This supplied energy can also remove impurity contents such as H, C, and O. However, the timing of the bias during the plasma halfcycle is crucial. Typically, the latter half of the plasma exposure time is considered optimal to prevent the simultaneous ignition of the plasma and bias, which can result in the breakage of ligand species. However, the plasma bias can be applied at any point in the plasma exposure (beginning, middle, end, pulsed, etc.) This phenomenon can lead to the incorporation of decomposed ligand species into the film, thereby increasing impurity content. To address this issue, we applied the bias near the end of the plasma exposure step. This technique aims to achieve a high-quality and more ligand-free film by leveraging the energetic ion impingement.

Our solution demonstrates successful performance when utilizing the specific gas mixture while maintaining a low background pressure and applying bias during the latter half of the half-cycle plasma exposure time at a deposition temperature of 300° C. In contrast, other gas chemistries have not yielded favorable superconducting parameters.

Example Process flow

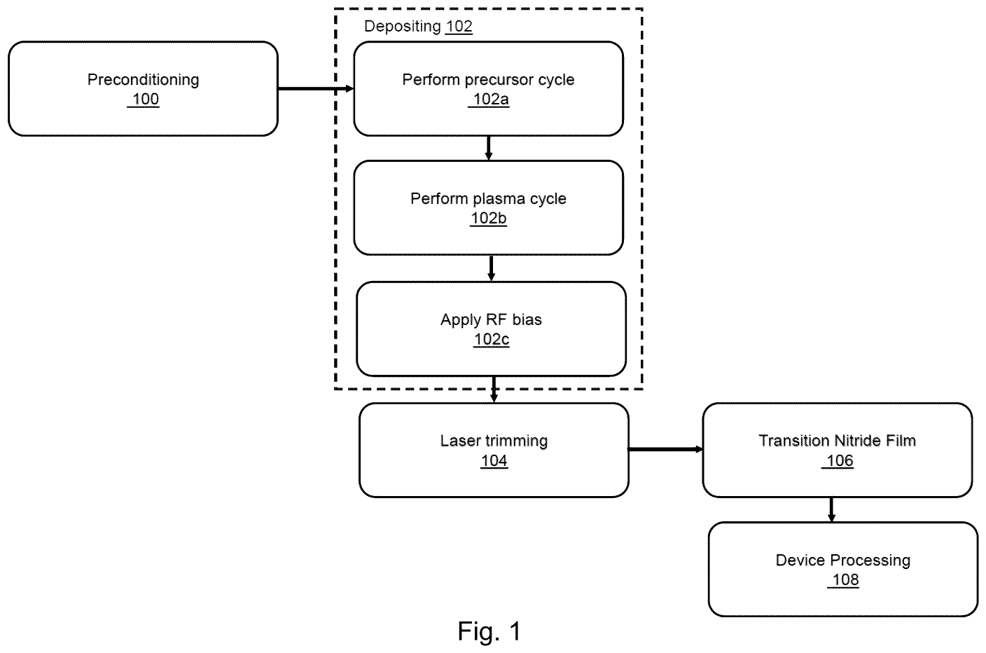

FIG. 1 illustrates a method of depositing a transition metal nitride film using plasma enhanced atomic layer deposition (PEALD) comprising the following steps.

Block 100 represents an optional preconditioning step comprising preheating the precursor, reducing the pressure of the reaction chamber, and performing one or more cycles each comprising a precursor exposure followed by a plasma exposure in the reaction chamber (e.g., but not limited to, at a pressure in the reaction chamber 0.022 Torr or below, 0.03 Torr or below, or 0.1 Torr or below, or 0.8 Torr or below for the precursor cycle and 0.003 Torr or below, 0.01 Torr or below, or 0.005 Torr or below, or 0.8 Torr or below for the plasma cycle). In one or more examples, the precursor delivery lines are heated to a temperature that prevents condensation, e.g., at least 60 degrees Celsius, and the substrate table is heated to a temperature of less than 400 degrees Celsius (e.g., 200 degrees Celsius≤T≤400 degrees Celsius). For the data presented herein, the precursor bubbler was heated to 60° C., the precursor delivery line was heated to 100° C. to prevent condensation. For the data presented herein, the substrate table maintained at 300° C. achieved the highest quality films

For the data presented herein, the preconditioning step comprising 15 preconditioning cycles using the deposition conditions (prior to actual deposition on the sample) produced a high-quality film.

Block 102 represents loading the substrate and depositing the transition metal nitride film on a substrate using plasma enhanced atomic layer deposition, comprising performing a number of deposition cycles. The deposition cycles each comprise:
(i) a precursor cycle 102a exposing the substrate to a precursor comprising at a pressure below 220 mTorr to form a precursor treated substrate. In one or more embodiments, the precursor (e . . . g, the precursor delivery lines) are heated to a temperature that prevents condensation, e.g., at least 60 degrees Celsius and the substrate table is heated to a temperature of at least 60 degrees Celsius.
(ii) a plasma cycle exposing the precursor treated substrate to plasma at a pressure below 3 mTorr and outputted from an inductively coupled plasma sapphire tube. In one or more embodiments, the plasma comprises Argon ions in a nitrogen atmosphere and the substrate table is heated to a temperature of less than 400 degrees Celsius (e.g., 200 degrees Celsius≤T≤400 degrees Celsius). The substrate table maintained at 300° C. achieved the highest quality films for the data presented herein.

In one or more embodiments, the gas composition of the background gas (e.g., atmosphere) in the reaction chamber during the precursor and plasma cycles contains no hydrogen (or less than 1% hydrogen). In typical examples, the atmosphere used for the plasma deposition is an argon and nitrogen atmosphere (e.g., 100% of the atmosphere contains nitrogen and argon), with no hydrogen or less than 1% hydrogen, and so that the ions bombarding the surface of the substrate during the plasma cycle are argon ions. To date, argon ions in a nitrogen atmosphere provided the best results for highest quality films, however it may be possible to use other atmospheres provided the atmosphere contains no hydrogen or less than 1% hydrogen.
(iii) applying an RF bias to the substrate during a final portion of the plasma cycle to promote bombardment of the substate with the plasma ions. The results presented herein show that a bias in the range 127-130 V provides good results. In some embodiments, bias voltages below this threshold may lack the energy required to remove ligand residues or densify the film, whereas voltages above 130 V may induce sputtering or re-sputtering, which may change the microstructures of the film, and subsequently increases the resistivity and reduce the superconducting critical temperature. However, the range of biases may vary from reactor to reactor.

It was discovered that the angle of incidence (or angular distribution) of the ions bombarding the surface of the substrate (relative to the surface normal of the substrate) during the plasma deposition cycle has a significant effect on the quality of the transition nitride film. The angle of incidence of the ions (and angular distribution) can be controlled by changing the pressure in the reaction chamber (sufficiently high pressures promote collisions of the ions with the background gas which randomize the angular distribution of the ions to increase the incidence angle relative to the surface normal). The angle can also be increased by tilting the substrate surface relative to the ions. As the angle/angular distribution is increased, the film quality increases and then degrades. More specifically, film quality is adequate for angles of 0 to 30 degrees, film quality is outstanding (or the best) for angles of 30-60 degrees, film quality is very poor for angles of 60-80 degrees, and with slight improvement (but still poor) for angles of 80 to 90 degrees (all angles relative to the surface normal of the substrate). Quality of the film is characterized as small grains that are not adequate for superconducting properties.

These angles are likely general phenomenon for ALD films and that the angles may change based on process conditions (higher pressure may broaden the good angles). Moreover the surface normal can be normal to a variety of surfaces. In other words, the angle of incidence can be varied by varying the angle of the substrate with respect to the ions, or using the angle of the feature on the substrate to provide the variable angle.

In typical examples, large grains, more tightly packed grains (so that oxidation cannot occur) provide for superior superconductive properties and optionally higher critical temperature Tc. It was further discovered that film quality (small grains) was particularly reduced at corners or intersections between planar surface and sidewalls and located within trenches, holes, openings, or vias. Film quality at such intersections can be increased using higher pressures (to increase the angle of incidence) or changing the angle of the substrate, or depositing on slanted surfaces, or depositing in wedge shaped or inverted cone shaped trenches, openings, holes or vias (as characterized by having a wider opening at top than the bottom). In this way, the ions impact the deposition surface at more ideal angles. However, care should be taken that the openings are not so wide that the film comprises filaments.

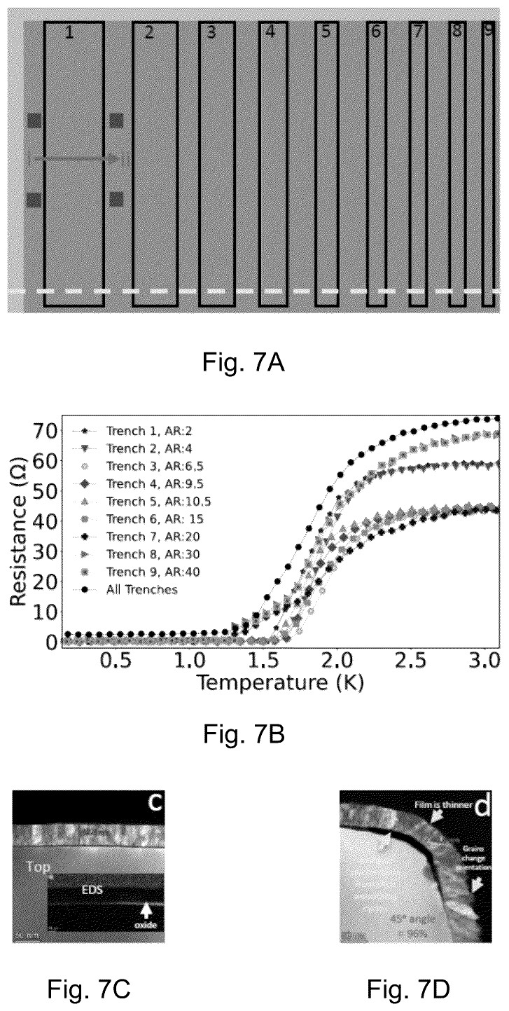

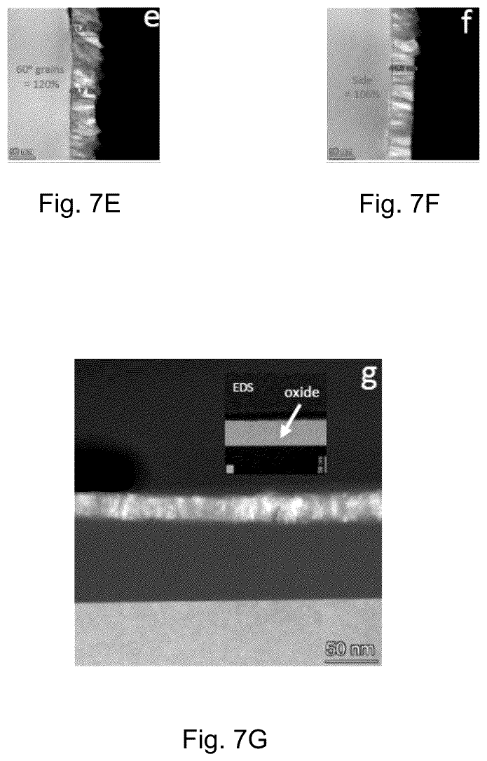

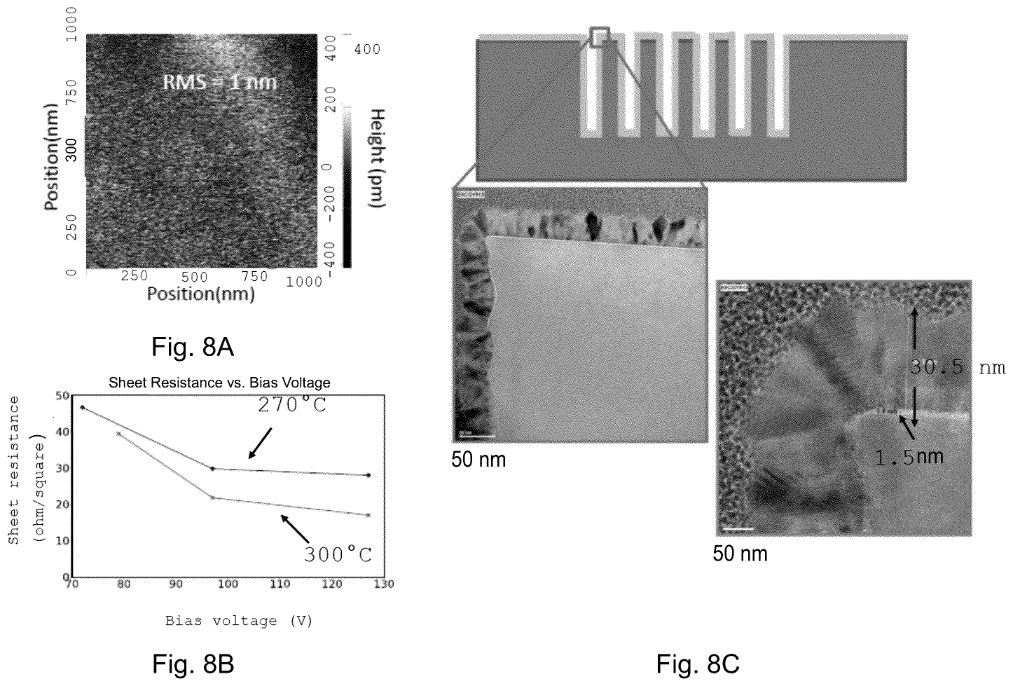

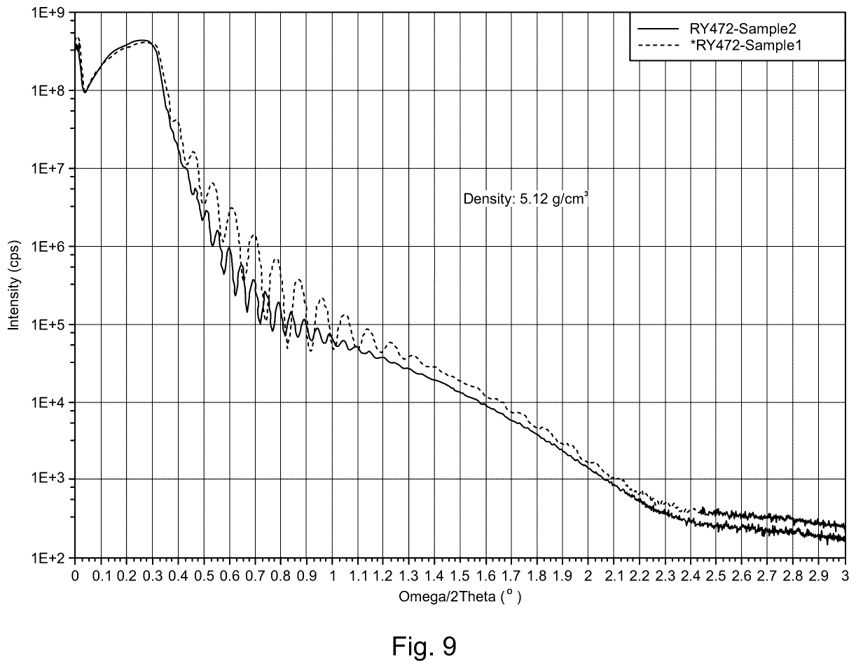

Block 104 represents performing a laser trimming step comprising laser ablation and laser cleaving of the film along edges and lips of the trenches to ensure that superconducting properties of the transition metal nitride are extracted within the trenches while bypassing lower-resistance planar regions of the transition metal nitride. In some embodiments, the laser trimming is performed to define channel regions for carrying current. This technique is useful in bypassing planar films or regions with the least resistance, thereby forcing the current to go through the trenches of interest. FIG. 7A shows and example wherein holes (the rectangles) are formed in the substrate and then removing the edges/sides of the holes into trenches by laser cleaving the edges on the lower side (yellow dashed line) and laser ablation on the top side.

In other examples, laser trimming is a method to isolate different regions of a semiconductor or superconductor device on two dimensional and/or three dimensional structures as compared to conventional lithography for which it is hard to pattern inside feature.

Block 106 represents the resulting transition metal nitride film.

Block 108 represents optional further processing of the film to manufacture a device or a planar film. The method can be used to fabricate devices or chips with interconnects, integrated superconducting device, or quantum devices/detectors, such as superconducting resonators, qubits, microwave kinetic inductance detectors (MKIDs), kinetic inductance parametric amplifiers (KIPAs), and superconducting nanowire single photon detectors (SNSPDs).

### Example Apparatus

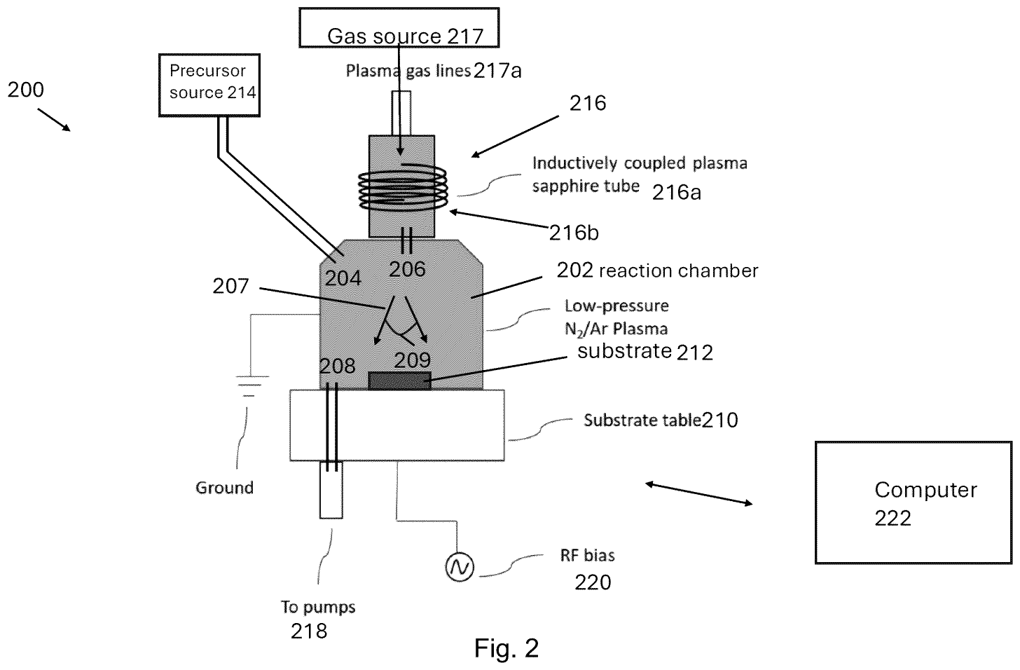

FIG. 2 illustrates an plasma enhanced atomic layer deposition (PEALD) system 200 comprising a reaction chamber 202 comprising a precursor inlet 204; a plasma inlet 206; and an outlet 208; a substrate table 210 for supporting a substrate 212 in the reaction chamber; a precursor source 214 coupled to the precursor inlet for sourcing a precursor to the substrate table; an inductively coupled plasma source 216 comprising a sapphire tube 216a coupled to the plasma inlet 206 to the reaction chamber; a pump 218 coupled to the outlet for reducing pressure in the reaction chamber; and an RF bias source 220 coupled to the substrate table for biasing a substrate with an RF bias. The plasma is formed using an inductively coupled plasma technique [40] comprising heating the gas atmosphere (typically argon and nitrogen) in a tube 216a (e.g., sapphire tube) using a varying magnetic field generated by a current flowing through a coil 216b coiled around the tube. The gas is heated to a temperature sufficiently high to ionize the gas to form the plasma. An biased electrode is positioned in the chamber to accelerate the ions to the substrate. Film quality can be increased using higher plasma pressures (to increase the angle 209 of incidence 207 of the ions) or changing the angle of the substrate 212.

However, other plasma configurations work (e.g., not just inductively coupled plasma), the main feature being the application of bias to the substrate (or adding an ion beam) and the ability to control angle of the ion bombardment either through the process or though the mechanical method of holding the sample with respect to the ions.

The system further comprises a computer 222 coupled to the precursor source, the RF bias source, the pump; and the plasma source, the computer configured to instruct the apparatus to perform a number of deposition cycles each comprising:
(i) a precursor cycle exposing the substrate to the precursor at a pressure (e.g., but not limited to, below 220 mTorr) to form a precursor treated substrate;
(ii) a plasma cycle exposing the precursor treated substrate to the plasma at a pressure (e.g., but not limited to a pressure below 3 mTorr); and
(iii) applying the RF bias to the substrate during a final portion of the plasma cycle. In one or more embodiments a bias at least 20 W was applied.

### Example Results

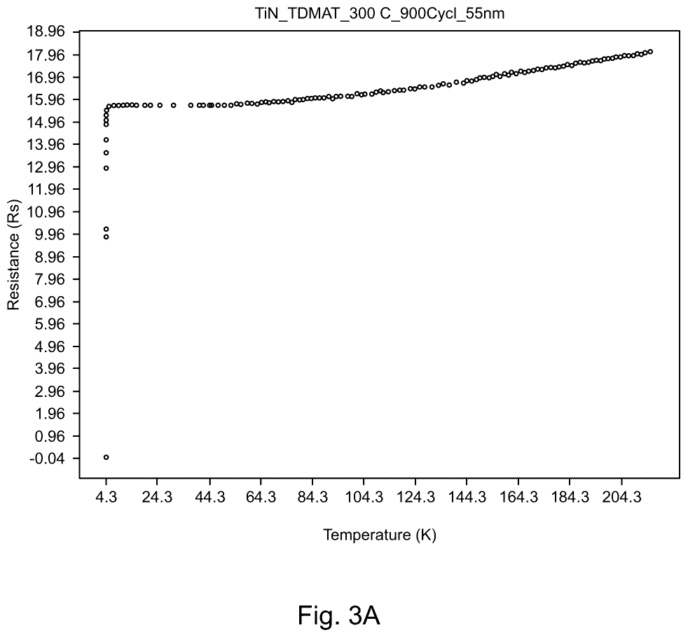

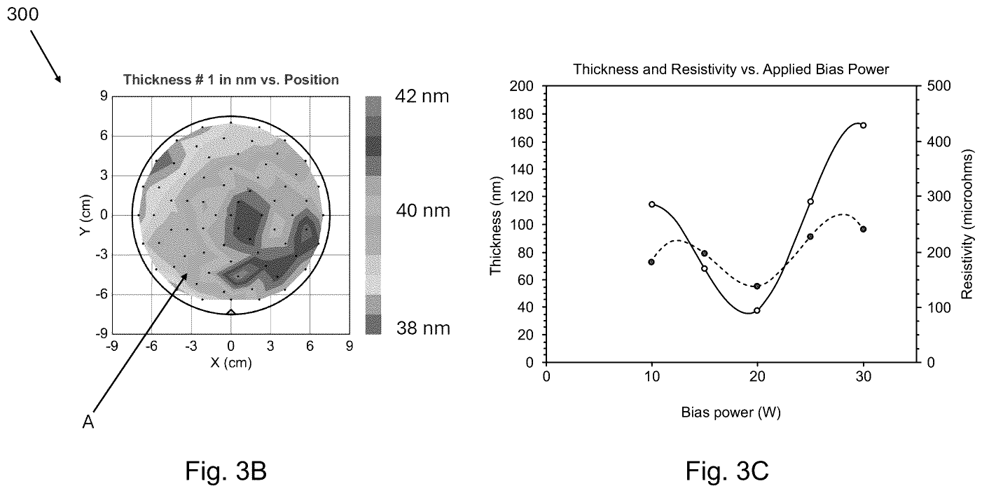

For the data presented in FIG. 3, the following process conditions were used.
1. Tetrakis (dimethylamido) titanium (TDMAT) was used as the precursor, and a nitrogen/argon plasma was employed at a substrate table temperature of 300° C.
2. A sapphire tube was chosen for the inductive coupled plasma to avoid ion-induced erosion caused by quartz tubes.
3. The precursor was heated to 60° C., and the delivery lines were maintained at 70° C. to prevent condensation.
4. The system was preheated with argon gas for 30 minutes.
5. Preconditioning was carried out with 25 cycles.
6. A low-pressure process was maintained, with a pressure of (a) e.g., 0.22 Torr during the TDMAT half-cycle and (b) e.g., 0.003 Torr during the plasma half-cycle.
7. A 20 W bias was applied for ion bombardment in the last 10 seconds of the 20-second total plasma exposure.

A key innovation in this methodology lies in the gas mixtures and the steps labeled as 2, 6, and 7. The supplied energy during the bias facilitates film densification, efficient removal of precursor ligand residues, and surface adatom diffusion, collectively contributing to the formation of high-quality films. Specifically, FIG. 3 illustrates a representative film manufactured using the above methodology to achieve a level of uniformity below 1.3% across a 6-inch wafer, a critical temperature (Tc) of 4.35 K for a film thickness (t) of 55 nm, along with a normal-state resistivity of 93 μmcm. These properties can be repeatably and consistently achieved for different samples. The superconducting parameters exhibit a level of comparability with equivalent sputtered films, while surpassing the performance reported in existing ALD techniques specifically tailored for quantum circuits and detectors.

### Second Working Example of Deposition of TiN Films

### Wafer

TiN films were successfully deposited on a 6-inch high-resistivity intrinsic/undoped Si (100) substrate with a resistivity greater than 10 kΩ-cm. The substrate used was a 675±15 μm prime float zone (FZ) wafer obtained from WaferPro LLC. It exhibited a single semi-flat bow/warp of ≤30 μm and a total thickness variation (TTV) of ≤5 μm. The wafer was also required to have ≤10 particles that are ≥0.3 μm. Prior to deposition, the wafers underwent a treatment with HF buffered solution followed by a cleaning process consisting of sequential treatments acetone, methanol, and propanol/isopropanol alcohol, followed by thorough rinsing with de-ionized water.

### Apparatus

An Oxford Flex II PEALD system (https://plasma.oxinst.com/products/ald/flexal-ald, incorporated by reference herein) was utilized using TDMAT as the precursor and a nitrogen/argon mixture for the plasma step. The PEALD reactor consisted of a water-cooled copper coil wrapped around a cylindrical alumina tube connected to a radio frequency (RF) power supply operating at 13.56 MHz with a maximum power of 600 W. This inductively coupled plasma (ICP) source generates radicals and ions during the plasma exposure step. In the FlexAL configuration, an external RF power supply operating at 13.56 MHz and up to 100 W was connected to the reactor table, enabling substrate biasing with fully automated RF matching [1].

We used a sapphire tube because it has less oxygen incorporation due to argon sputtering.

The precursor temperature was set to 60° C., and the pulse period for the deposition cycle was 300 ms. During the TDMAT half-cycle, the chamber pressure was 220 mTorr and 3 mTorr for the plasma half-cycle. The argon flow rate through the precursor cannister was maintained at 30 sccm, and 10 sccm during the plasma halfcycle. The precursor delivery line was heated to 100° C. to prevent condensation. High-purity nitrogen and argon gases (>99.999% purity) were used to generate the plasma, with a flow rate of 10 sccm each. The gases were stabilized for 5 s before plasma ignition with pulse periods of 20 s, a power of 300 W, an intermittent average bias voltage step of −127 V, at a deposition temperature of 300° C. At this temperature, the substrate table was maintained for preheating while flowing argon gas at a rate of 200 sccm for 10 mins, and precondition step with 25 cycles before actual deposition.

To enhance film quality, an ion bombardment intermittent step was introduced by implementing substrate biasing during the final half-seconds of plasma exposure. The bias was applied in the last 10 seconds of the 20 second total plasma exposure. Typically, the latter half (10s) of the plasma exposure time is considered optimal to prevent the simultaneous ignition of the plasma and bias, which can result in the breakage of ligand species. This methodology serves to enhance film densification, eliminate precursor residues, and facilitate the diffusion of surface adatoms.

Other investigations have demonstrated that maintaining low pressure effectively reduces sputtering in ICP tubes, with a more pronounced impact observed in quartz tubes as opposed to alumina tubes [2,3]. Throughout the plasma exposure, there is a conspicuous reduction in the concentration of dissociated nitrogen, resulting in comprehensive nitridation. Ion bombardment resulting from substrate biasing exerts a substantial influence on the growth, microstructure, and composition of the TiN films. This process induces modifications in the film's properties, attributed to enhanced adatom mobility due to momentum transfer imparted by the bombarding ions, highlighting multi-grain sizes. Film thicknesses were determined using XRR and TEM, while XRR assessed mass density and surface roughness. AFM validated film roughness (1 μm×1 μm scan area). We explored different process parameters include temperature, bias time, cycle, etc. to get an optimized superconducting TiN. With N₂/H₂, we achieved good resistivity but encountered adhesion issues. Using NH₃ resulted in higher resistivity compared to N₂/H₂ and N₂/Ar. For this study, the best quality film was obtained using N₂/Ar chemistry. The results are summarized in the Table I.

TABLE I
Summary of PEALD TiN properties achieved using
N₂/Ar, H₂/Ar, and NH₃/Ar chemistries

| Plasma | Cycle | Thickness | Sheet Resistance | Resistivity |
|---|---|---|---|---|
| Gas | (#) | (nm) | (ohm/sq) | (microohm-cm) |
| N₂/Ar | 900 | 40.50 | 17.30 | 70.07 |
| H₂/Ar | 1500 | 57.98 | 20.10 | 116.53 |
| NH₃/Ar | 1500 | 89.85 | 13.00 | 116.93 |

Two sample thicknesses, approximately 40 nm and 80 nm, were chosen based on device performance analyses and a focus on bulk properties, respectively. Film thicknesses in the 40-50 nm range consistently produced high-quality superconducting microresonators. ^{4,14-16}. TDMAT and N₂/Ar gas mixture deposition occurred at 300° C. with an average RF substrate bias of ≈−127-130 V. This optimized voltage enhances film densification and eliminates ligand residues, aligning closely with studies in Ref. [^{31,33}] that extensively examined ion energy as a function of bias voltage.

The reactive sputtering setup for TiN deposition used for the comparative study follows the configuration reported in Ref. [4].

### Characterization

To comprehensively evaluate the quality of our films in planar and intricate 3D structures, various characterization techniques were employed, including atomic force microscopy (AFM), contactless sheet resistance measurements, cryogenic DC electrical measurements, scanning electron microscopy (SEM), X-ray photoelectron spectroscopy (XPS), X-ray diffraction (XRD), X-ray reflectometry (XRR), secondary ion mass spectrometry (SIMS), transmission electron microscopy (TEM), energy-dispersive X-ray spectroscopy (EDS), and electron energy loss spectroscopy (EELS). Superconductivity measurements were conducted in a cryogenic system cooled by liquid helium (LHe), utilizing a current source and voltmeter. Each ALD cycle resulted in a deposition rate of approximately 0.65 Å, ensuring over 95% uniformity across a 6-inch wafer, as evidenced by the sheet resistance map and minimal surface roughness of 1 nm. Table II summarizes properties of a 40 nm TiN film deposited via PEALD and reactive sputtering. In PEALD, adjusting ion energy, film thickness, and deposition temperature can increase impurity levels, raising L_{□}.

TABLE II
The crystal structure, compositional, and superconducting properties
of a 40 nm -thick planar sputtered and PEALD TiN film.

| Properties | PEALD TiN | Sputtered TiN |
|---|---|---|
| Stoichiometric ratio (Ti:N)^{a} | 0.95 | 1.00 |
| Mass density (g/cm³) | 5.12 | 5.12 |
| Crystal orientation | (111) | (111) |
| Crystallinity (%)^{b} | X: 78.3, A: 21.7 | X: 88.6, A: 11.4 |
| Impurities concentration (%)^{c} | H: 2.5, C: 1.0, | H: 0.66, C: 0.025, |
| | O: 0.3 | O: 0.1 |
| Critical temperature (K)^{d} | 4.35 | 4.00 |
| Residual resistivity ratio (RRR) | 1.30 | 1.20 |
| Sheet inductance (pH) | 3.7 | 12.0 |

^{a}The stoichiometric ratio was determined through depth profiling XPS.
^{b}Here, X = crystalline and A = amorphous material(s). Refer to section 2.2 for details.
^{c}The impurities were determined through SIMS, with H = hydrogen, C = carbon, and O = oxygen.
^{d}The T_{c} represents the temperature corresponding to a 50% reduction in R_{□} from its value at 5.5 K.

### 1. Superconductive Properties.

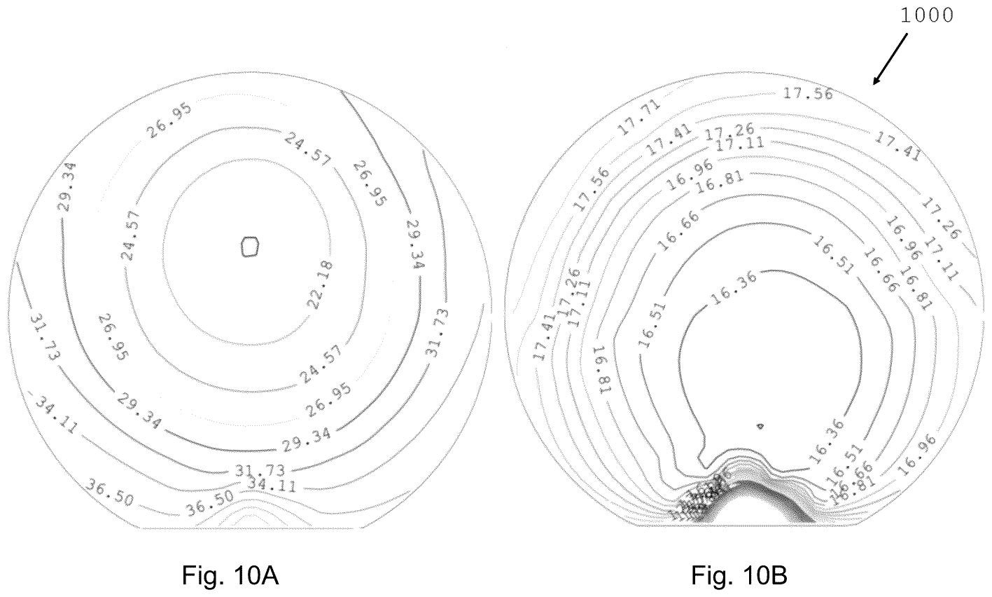

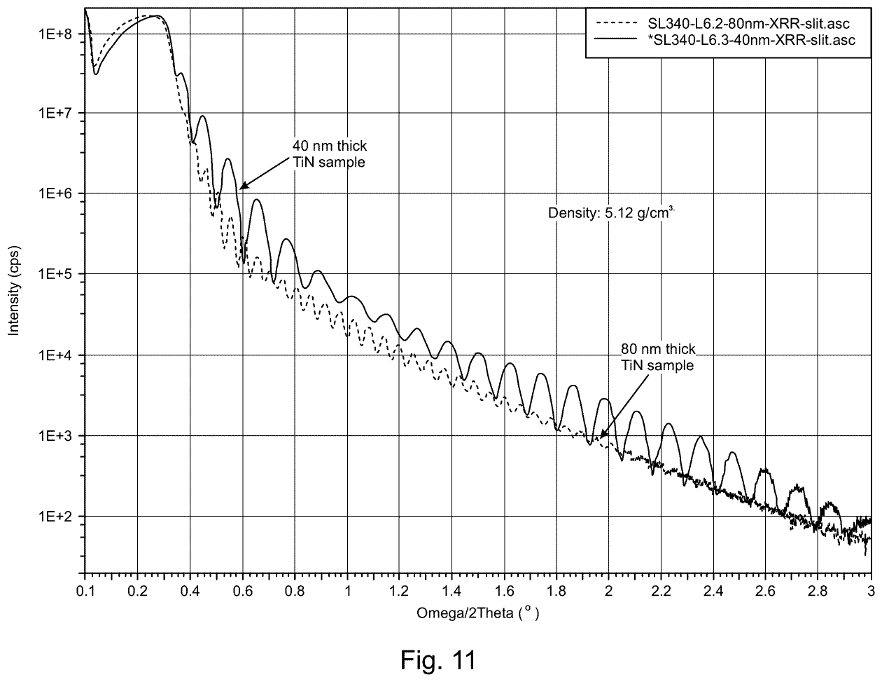

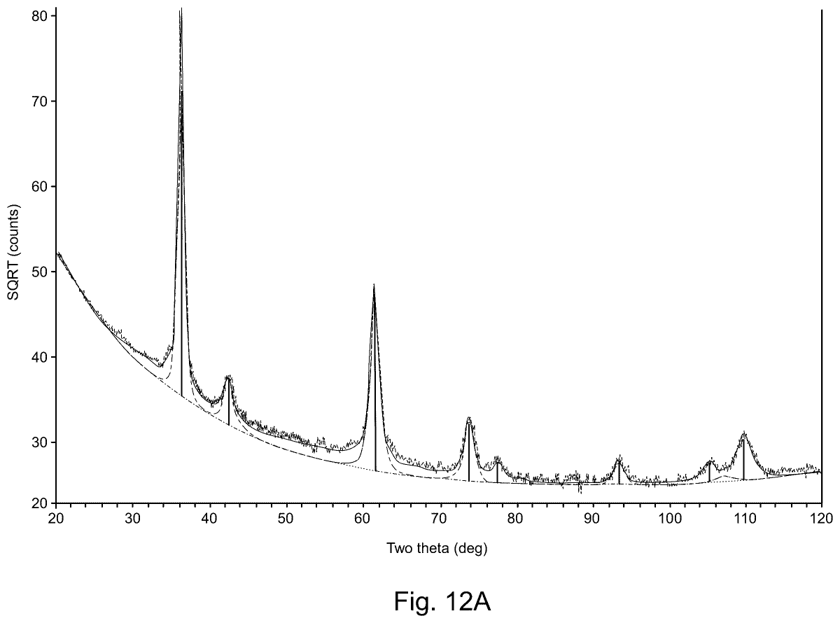

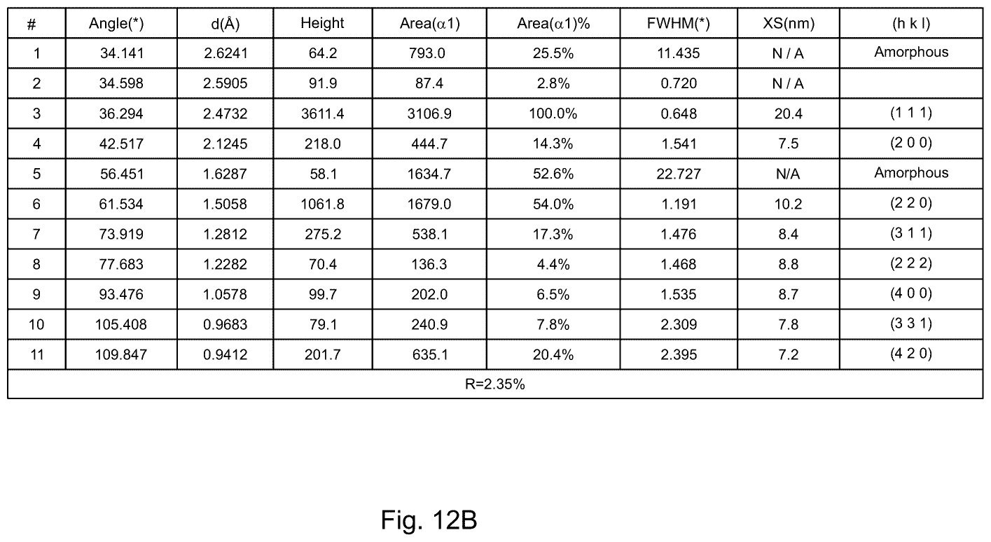

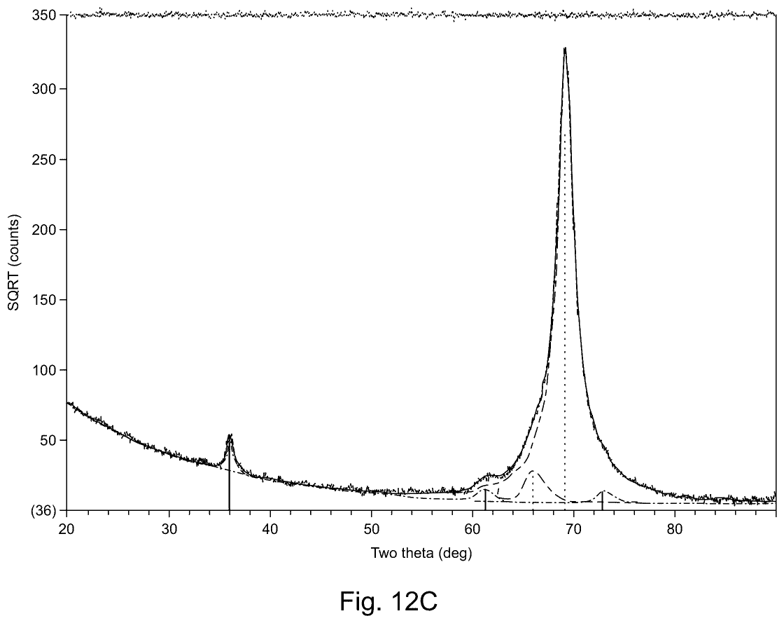

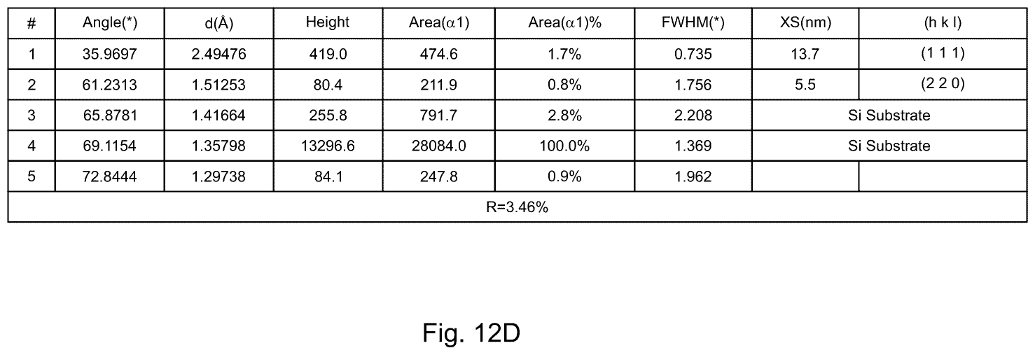

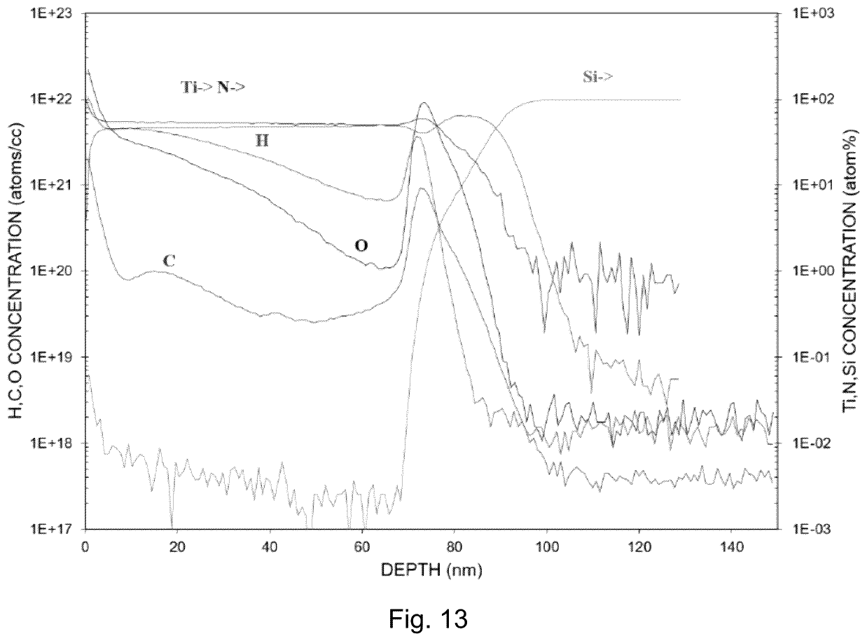

FIG. 10 illustrates a 6-inch PEALD TiN wafer was precisely diced into chips, patterned with van der Pauw structures, wire-bonded to a carrier chip, and measured for superconductive properties within a cryogenic system.

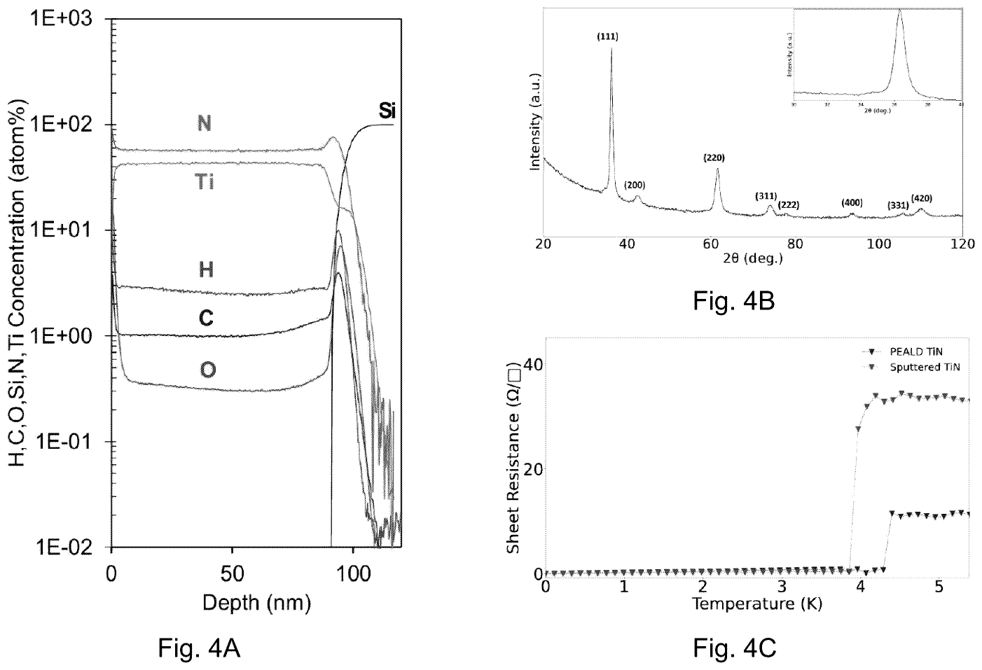

FIG. 4A shows SIMS quantifying impurities, revealing H, C, and O levels of approximately 2.5%, 1%, and 0.3%, respectively. XPS depth profiling indicated an average Ti: N ratio of 0.95. Additionally, XRD identified the phase, crystal structure, and texture alignment toward (111), as illustrated in FIG. 4B; the lattice constant measures 4.283 Å. Crystal orientation depends on growth pressure, substrate temperature, grain boundary density, and ion impact. 14,35 FIG. 4C presents a T_{c} comparison between PEALD and sputtered TiN, with 4.35 K and 4.00 K, respectively.

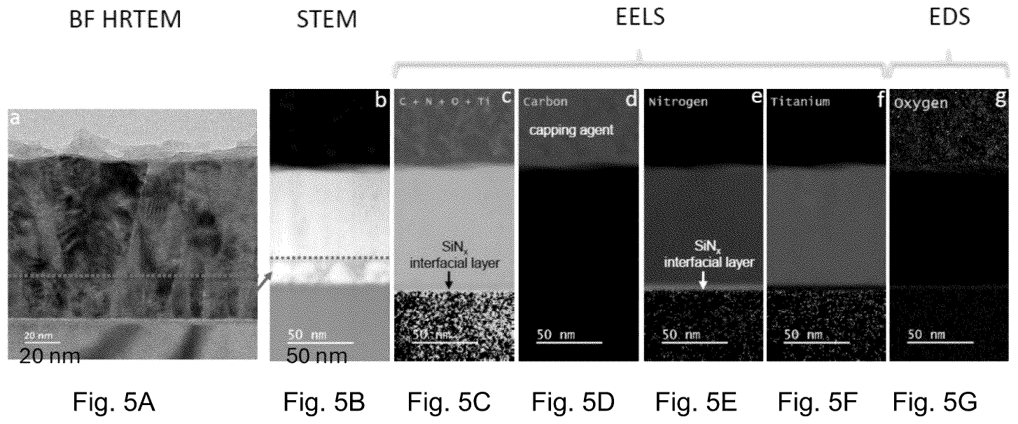

FIG. 5A displays a BF HRTEM of an 80 nm planar film with multiple columnar grain structures, featuring grain widths reaching approximately 60 nm. The crystallite sizes are estimated by XRD to be 20, 10, 8, and 7 nm in different directions. The film appears very smooth, resembling a multilayer stack consisting of SiNₓ, a TiN nucleation layer, and a TiN “bulk” film, as depicted in the STEM image of FIG. 5B.

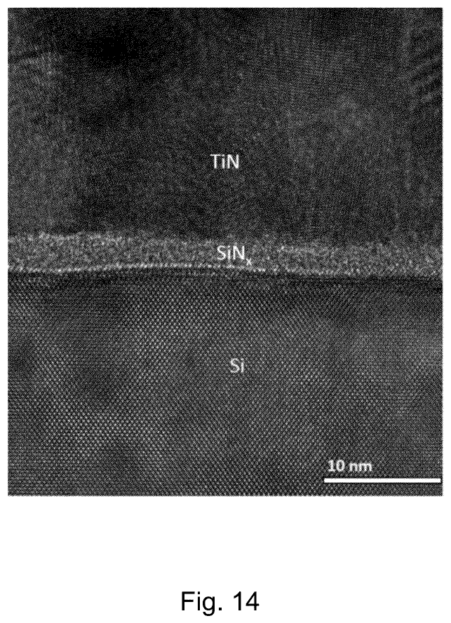

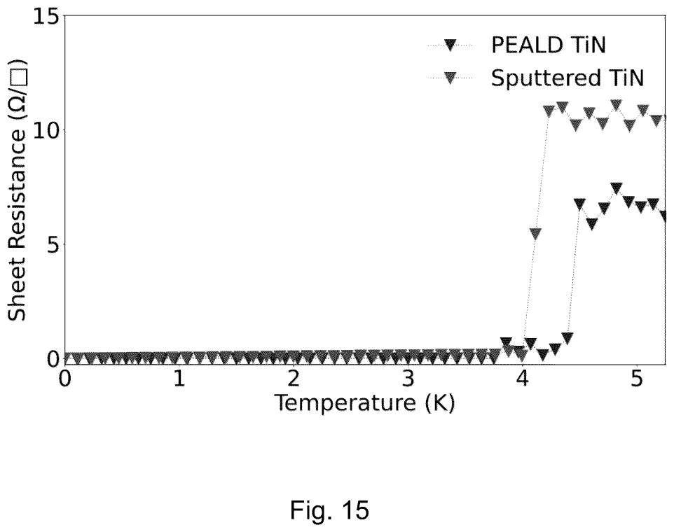

FIG. 5C-5F, (EELS), FIG. 5G (EDS), and FIG. 14 illustrate an approximately 2 nm-thick SiNₓ interface layer exists between the TiN film and the Si wafer. The observed incubation period is likely a result of the initial nucleation triggered by exposure to nitrogen plasma. This initiation subsequently supports the nitridation process of silicon-a phenomenon prevalent in nitrogen-based TiN growth chemistries ^{5,20} as opposed to gas chemistries that do not involve nitrogen.³¹⁻³³

Nine DRIE trenches were employed instead of vias to streamline 3D structure characterization, enabling measurements from the sample's front side. Utilizing 3D architecture in SDs addresses interconnection crowding and facilitates hybridization. In Ref [¹¹], TiN served as superconducting TSVs for integrating transition edge sensors with SQUID readout architectures, a strategy echoed in Ref. [2,12,13] for routing signals to resonators, compacting devices while preserving coherence. Trenches with AR ranging from 2 to 40 were fabricated to establish future design guidelines for superconducting TSVs.

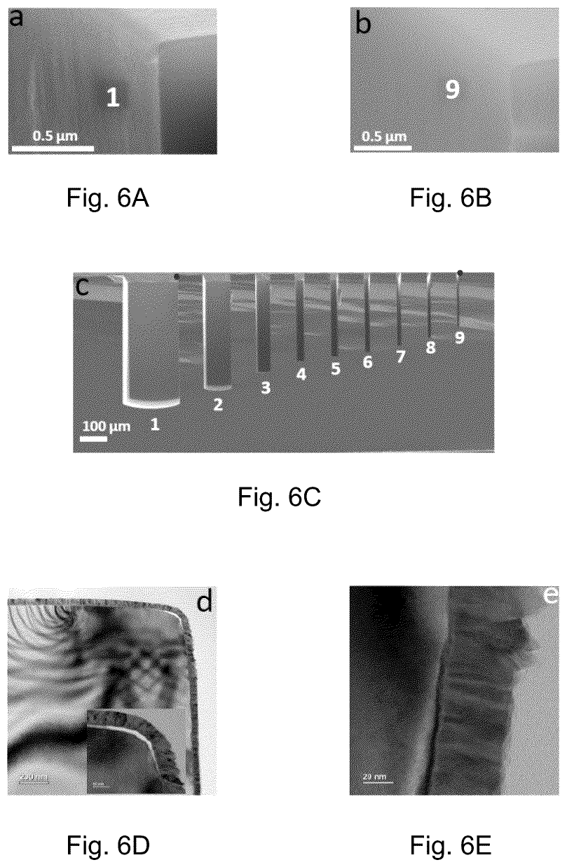

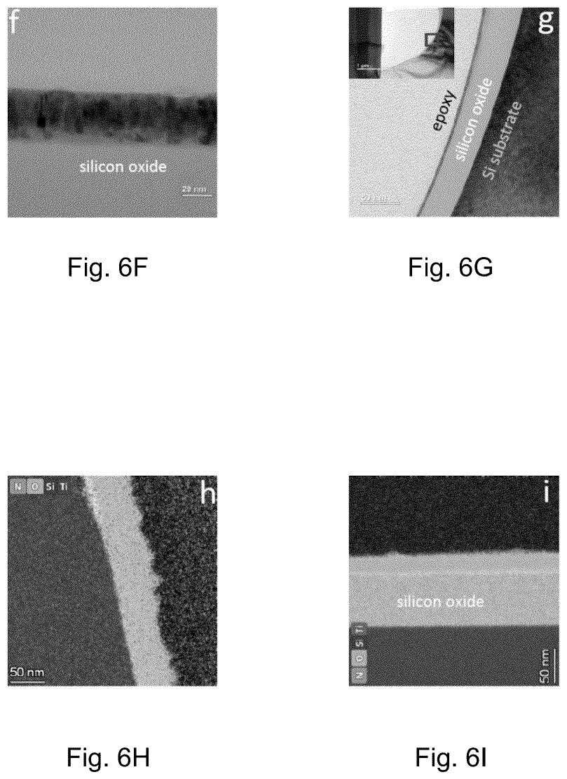

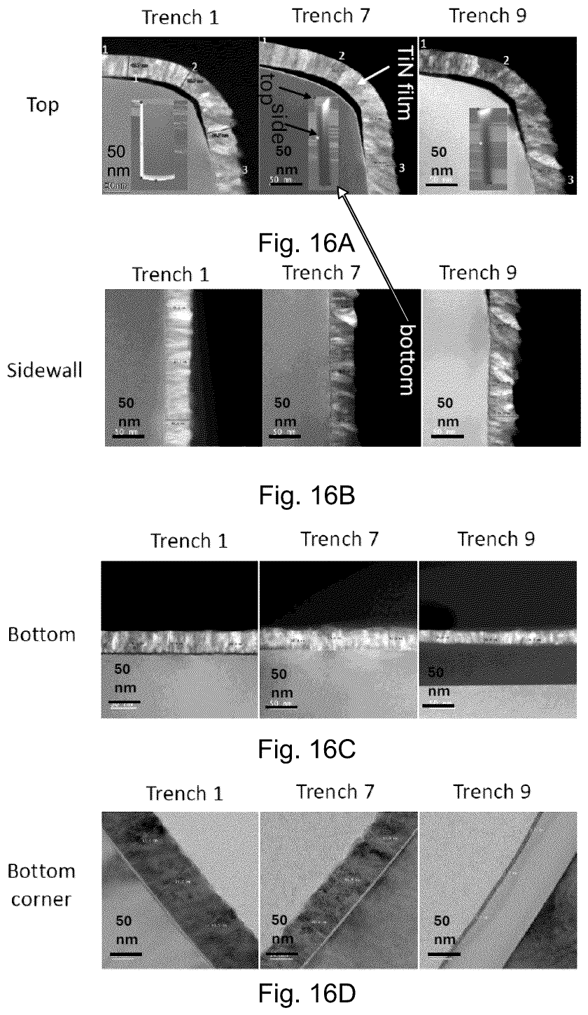

To smooth the sidewalls and eliminate DRIE scalloping, thermal oxidation and HF wet etching were applied (section 3.2). Subsequently, TiN was deposited within the trench structures using the same process as the 40 nm thick planar film. High-resolution SEM images in FIG. 6A and FIG. 6B show Trenches 1 and 9, respectively with a highly conformal PEALD TiN. FIG. 6(c) shows SEM image of all trenches with PEALD TiN post-DRIE. FIGS. 6D-6I focus on Trench 9, which has the highest AR of 40. In FIGS. 6D and 6E, the BF HRTEM image shows a film with a smooth texture and a rough morphology at the top corner, and rougher than Trenches 1 and 7 (FIG. 16). Notably, an oxide layer is visible, concentrated at the top corners, consistent with features observed in the significant corners of Trenches 1 and 7. The films along the sidewalls in FIG. 6E exhibit a slightly rougher texture and randomly oriented grains compared to the top surface in FIG. 6D and FIG. 16A of Trench 9. A significantly thick oxide layer at the base in FIG. 6(f) and bottom corner of FIG. 6G shows the impact of high AR and the inability of the post HF-treatment to completely remove the oxide within the necessary timeframe. In contrast, FIG. 16 shows trenches 1 and 7 did not experience this issue. Stress distribution resulting from the underlying oxide could potentially lead to different superconducting properties. EDS maps in FIGS. 6H and 6I for FIGS. 6D and 6F respectively show a well balanced Ti/N mixture.

Using laser trimming, TiN was removed from trench edges to direct current flow down one wall, along the bottom, and up the other side, bypassing the lower-resistance planar TiN (FIG. 7A). Without this step, T_{c} measured around 4.35 K for the planar sample. Superconductivity assessments were performed using a four-wire setup on each trench and between Trenches 1 and 9, totaling 10 measurements. During this period, the temperature gradually decreased from 3 K to 100 mK over 30 minutes. A compact radiation shield protected the trenches from 3 K radiation, aiming to characterize T_{c} within each trench, identifying superconducting degradation points. I_{c} across trenches was not measured due to power requirements exceeding the cooling power of the mK stage. We are exploring robust methods for high I_{c}/T_{c} superconducting TSVs. In Ref. [¹²], a cross bridge kelvin resistor was used to extract I_{c} values within vias.

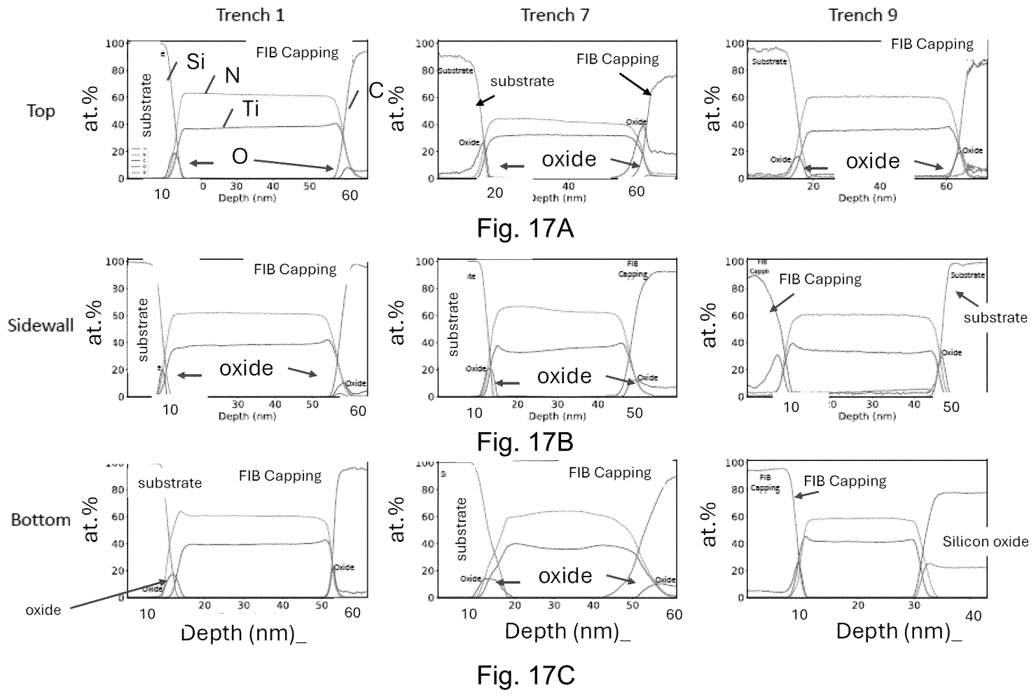

FIG. 7B shows superconductivity in all nine trenches, including between Trenches 1 and 9, with polycrystalline grains at the corners, sidewalls, and bottoms. Peculiarities in step coverage were noted, revealing differences in film morphology especially at the top corners, top sidewalls and bottom corners of Trenches 1,7, and 9. Grain rotation at these locations suggests morphology variations due to the incident ion flux angle. We analyzed step coverage and composition in Trenches 1,7, and 9 (section 4.1) to understand their impact on T_{c}. This approach, combined with superconductivity measurements, offers insights into the film's performance in 3D structures with varying ARs. TiN film exhibited faceting and changes in grain orientation at different angles, influencing film thickness and roughness (FIGS. 7C and 7G). FIGS. 7D-7F revealed reentrant material, elongated, and rotated/misoriented grains in corners and sidewalls, contributing to an overall rougher surface. EELS data analysis (FIG. 17) showed consistent TiN stoichiometry without detectable carbon in Trench 1. Trench 7 exhibited identical TiN stoichiometry for the bottom and sidewall, with a 45% increase in nitrogen compared to the top corner. Trench 9 showed consistent TiN stoichiometry for the top corner and sidewall with the presence of carbon, and the bottom had no carbon content.

Transitions around 2 K were typical for Trenches 1-6, at about 60% reduction in R_{□} from its value at 3 K while Trench 7 displayed a T_{c} breakpoint (FIG. 7(b)), highlighting multiple transition levels at lower temperatures (<1.5 K). Trenches 1 and 2, with greater widths, exhibit higher resistance than Trenches 3-6. Trenches 8 and 9 show much higher resistance due to significant film thickness variations at their bottom corners (as shown in FIG. 16).

The impact of trench geometry on superconducting state degradation ¹² highlights morphology and composition changes, for developing mitigation strategies. Disordered lattice structures can reduce T_{c} by disrupting coherent electron motion. Ion energy's influence on film growth ³⁶⁻³⁸ is discussed (section 4.2), attributing the “breaking” mechanism to ions

$$( {N}_{2}^{+} / {Ar}^{+} )$$

mainly normal to the substrate in high AR trenches. Ref. [³⁸] indicate that high AR trenches (>10) might show a recombination-limited phenomenon, with saturation occurring last at the trench bottom. Grain misalignment due to impact angle changes is seen at the top and bottom corners but not at lower sidewalls and trench bottoms (as shown in FIG. 16). Experiments, such as KOH etching producing 45° side-walls instead of 90°, are proposed to explore sidewall angle effects. Additionally, substrate bias optimization and trench modifications for each AR are suggested.

### 2. Materials Characterization

### X-Ray Diffraction and X-Ray Reflectivity

The samples were mounted directly to the diffractometer with a vacuum chuck sample stage. Grazing incidence XRD (GIXRD) data were collected using a Bruker D8 UltraGID 7-axis diffractometer equipped with a copper X-ray tube, parallel beam optics, a 0.5° parallel slit analyzer, and a scintillation detector. Grazing angles of 0.36° and 0.38° were used for Sample1-40 nm and Sample2-80 nm, respectively. For X-ray reflectivity (XRR), the samples were mounted directly to the diffractometer with a vacuum chuck sample stage. Data were acquired with a Bruker D8 Discover UltraGID 7-axis diffractometer equipped with a copper X-ray tube, parallel-beam optics, a narrow XRR receiving slit, and a scintillation detector [5].

### Phase Identification, Semi-Quantitative Analysis, Crystallite Orientation (Simple Texture) and Crystal Size

Crystalline phases are distinguished by analyzing the positioning and relative intensity of peaks within experimental X-ray diffraction (XRD) data, comparing them to entries in the ICDD/ICSD diffraction database. Reference markers within the phase serve as indicators of where the anticipated experimental peaks should be situated on the two-theta scale, while the markers' relative heights denote the expected peak intensities for a fine grained and randomly oriented phase. It is crucial to note that while XRD is sensitive to crystal structure, it has limited sensitivity to elemental or chemical state compositions. Hence, the actual chemistry of the matching phase may differ from that of the reference card. Identifying amorphous phases differs from crystalline phases due to their lack of distinct, sharp peaks. Instead, amorphous phases exhibit a few broad peaks, approximately 100 times wider than a crystalline peak. Additionally, the positioning of an amorphous peak is determined based on shortrange nearest neighbor distances, primarily among elements with the most electrons, rather than the material's composition. Consequently, XRD cannot ascertain the composition of amorphous materials. Semi-quantitative analysis involves employing WPF (whole pattern fitting), a subset of Rietveld Refinement that incorporates all intensity above the background curve.

This technique necessitates knowledge of either the structure factors and atomic locations or the reference intensity ratio for all identified phases. During this procedure, parameters such as structure factor (linked to concentration), lattice parameters (associated with peak position), peak width, and peak shape are refined for each phase to minimize the R value-an estimation of the agreement between the model and experimental data across the entire pattern. The WPF representations comprise a difference curve displayed at the pattern's top, demonstrating the discrepancy between the experimental data and the modeled pattern. This difference curve is represented in square-root intensity to highlight minor dissimilarities between the patterns. If an amorphous phase registers within the XRD pattern, it necessitates assigning a density to quantify its presence accurately. Any discrepancy in this density directly impacts the quantification of the amorphous material. Consequently, while the relative concentrations of crystalline phases remain accurate, the absolute concentrations incur an error proportional to the inaccuracy in the amorphous concentration.

It is important to note that the size of the amorphous peak significantly relies on the background's shape in this region, and the assignment of the background is subjectively determined by the analyst. The determination of crystallite orientation involves collecting XRD data in a symmetrical theta/two-theta geometry to examine crystallographic planes parallel to the sample's surface. The peak ratio method is employed to ascertain crystallite orientation, utilizing the areas of multiple peaks from diverse crystallographic directions. These intensities are adjusted concerning that of a randomly oriented phase, obtained from the ICDD/ICSD database. Each peak undergoes profile fitting, and the resulting area is utilized to derive intensity ratio values recorded in a summary table. These values represent the percentage of crystallites oriented in three or more distinct crystallographic directions. The peak with the least contribution to the intensity is presumed to originate from randomly oriented grains. This contribution is subtracted from the totals of other peaks to establish the random fraction. Profile fitting is employed to ascertain peak positions, widths, and areas, crucial for calculating crystallite orientation [5].

The crystallinity of a sample is determined by modelling all the peaks present in an XRD pattern. The crystallinity calculation assumes the amorphous phase has the same chemical composition as the crystalline phase and is reported as % crystallinity. The experimental intensity must be corrected for instrumental background and Compton (incoherent) scatter. Compton's scatter is an exponential type curve which subtracts a different intensity value from each individual measured data point, and the subtracted intensity is a function of the total intensity of the unknown sample. This correction is complex and difficult to apply so as a result, common practice is to model and exclude the sample background, which contains both the instrument background and at least a portion of the Compton background. Finally, the resulting peaks are profile fit, and assigned as either amorphous or crystalline, depending upon such factors as density of material, standard (modeled) locations of amorphous peaks, FWHM (full width at half maximum) of the peak, and signal to noise ratios. Once all peaks are assigned, the % crystallinity is simply calculated as:

$$\% crystallinity = \frac{Total area of crystalline peaks}{Total area of all peaks}$$

where the total area of all peaks includes both crystalline peaks and amorphous scatter intensity. The crystallite size of a phase is determined by modeling the peaks in the XRD pattern and translating the Full Width at Half Maximum (FWHM) of each peak directly to crystallite size. The broadening of an observed diffraction peak can be characterized by its FWHM value at a specific 2θ angle. The FWHM of a peak is a mathematical combination (convolution) of the specimen broadening FW(S) and the instrumental broadening FW (I). Therefore, the instrumental broadening is determined using a NIST standard and then subtracted from the observed diffraction peak to yield the specimen broadening. If the crystallites (i.e., crystalline domains) in the specimen are free of lattice strain, their average size can be estimated from the specimen broadening FW(S) of any single peak in the observed pattern according to the Scherrer formula:

$$Crystallite Size = \frac{K \cdot λ}{FW ( S ) \cdot cos ( θ )}$$

In this equation, θ is the peak position, λ is the X-ray wavelength, and K is the shape factor of the average crystallite. A spherical shape is assumed for K in the crystallite size calculation. Peak fitting is required to determine the peak positions and widths used for crystallite size analysis. When crystallite microstrain is present, the Scherrer method for determining crystallite size will systematically underestimate the crystallite size since it ignores the microstrain contribution to peak broadening. Profile fitting is used to determine the peak positions and widths that are used for crystallite size and microstrain analysis. Beneath each profile fitting figure is a table with the detailed fitting results for each peak. The peaks highlighted in blue in the tables were used for determining the crystallite size for each sample. It is noted that the minimum peak width and therefore the maximum crystallite size is determined by the diffractometer resolution.

It is also noted that determining crystallinity by XRD requires significant subjectivity, since the analyst assigns the peak intensities to either crystalline or amorphous. In many cases, this is judgmental, since a very small crystallite size may produce a broad peak which appears to be almost amorphous. Note that the crystallinity results are also very sensitive to the exact shape of background. While great care was taken to assign the background, it is still a subjective human process that has a fair amount of uncertainty. Profile fitting or whole pattern fitting is used to determine the peak positions, widths and areas necessary for the percent crystallinity calculations. Beneath each profile fitting figure is a table detailing the individual peak fitting results. The amorphous peaks are highlighted in yellow.

### 2.3 X-Ray Photoelectron Spectroscopy

XPS measurements were conducted using a Kratos Axis Ultra system with a monochromatic AlKα source (hv=1486.6 eV) operating at 150 W and a base pressure of <1.0×10⁻⁹ Torr in the analysis chamber. The X-rays were angled at 45°, and the hemispherical analyzer collected photoelectrons at 90° to the sample surface. The spot size on the sample was approximately 700 μm×300 μm. High-resolution spectra were acquired at an operating current of 10 mA, voltage of 15 kV, and a resolution of 50 meV with a pass energy of 10 eV for each sample. The spectra were aligned by referencing the C1 s (284.6 eV) transition and fitting the Ti2p, N1 s, O 1 s, and C 1s peaks. To perform depth profiling, a 2kVAr⁺ milling process was carried out with a raster size of 3 mm×3 mm for 10 minutes. The instrument was operated using Vision Manager software v. 2.2.10 revision 5, and the spectra were analyzed using CasaXPS software (CASA Software Ltd).

### Secondary Ion Mass Spectroscopy

The SIMS analysis employed a Phi Adept 1010 quadrupole tool with a primary ion energy of 2 keV. Contamination profiles, specifically for hydrogen, carbon, and oxygen, were acquired using negative atomic ions. Composition profiles for titanium, nitrogen, and silicon were obtained using positive cesium cluster ions [5].

### TEM, EDS and EELS

The specimens were coated with protective carbon, sputtered with Pt, as well as e-W and i-W. Lamellae were fabricated employing the lift-out preparation methodology, using the Thermo-Fisher (FEI) Helios UC FIB-SEM system and the Thermo-Fisher (FEI) Helios UX FIB-SEM. Transmission electron microscopy (TEM) images were captured using a JEOL JEM-F200 Multi-Purpose Electron Microscope, which was operated at an acceleration voltage of 200 kV and was equipped with a Gatan One View CCD camera. Energy-dispersive X-ray spectroscopy (EDS) data were collected via a Dual JEOL JED-2300 Dry SDD EDS detector, and electron energy loss spectroscopy (EELS) data were gathered with the GIF Continuum ER detector. Subsequently, the acquired data underwent processing using the DigitalMicrograph® and Velox® software packages [6].

### 3. Process and Cryogenic DC Characterization

### 3.1 Planar TiN

To access the superconducting properties, the TiN samples deposited with SPR 220-3.0 photoresist and spin-coated at 3000 rpm for 30 s, followed by a soft bake at 115° C. for 90 s. Lithographic patterning was executed without a mask, in which van der Pauw structures were defined, employing the MLA-150 system. The applied exposure dose was 350 mJ/cm² at a laser wavelength of 405 nm. AZ 300 MIF was used for development. Afterwards, a reactive-ion etching (RIE) process was implemented using a mixture of BCl₃/Cl₂/Ar gases at flow rates of 30/30/10 sccm, and at a pressure of 5 mTorr. The plasma was generated with an ICP RF power of 400 W and a bias RF power of 50 W. This was followed by a post-etching treatment involving an O₂ plasma step. To complete the process, the resist material was removed using a combination of acetone, isopropyl alcohol, and deionized water. The prepared samples were then diced into individual chips using a Disco DAD 320 dicing saw, and wire-bonded onto a carrier chip. The superconductivity parameters were assessed using a current source (Keithley 224) and a voltmeter in a cryogenic system cooled by liquid helium (LHe), utilizing a specialized dipstick apparatus.

### TiN in 3D Trenches

For the trenches, the wafers underwent two RCA cleaning procedures. The first RCA clean step was carried out using 4200 ml of DI water, 2520 ml of NH₄OH, and 840 ml of H₂O₂ at a ratio of 5:3:1. Subsequently, the second RCA clean step was conducted, involving 5040 ml of DI water, 1260 ml of HCl, and 1260 ml of H₂O₂ at a ratio of 4:1:1, all performed at 80° C. for 10 minutes. Following the cleaning steps, an AZ 10XT-520 cP photoresist was applied through spin-coating at 2000 rpm for 40 s, followed by a soft bake at 115° C. for 120 s. The wafers were then subjected to a rehydration hold lasting for 1 hr. Lithographic patterning was executed without the use of a mask, utilizing the MLA-150 system. This process involved an exposure dose of 500 mJ/cm² at a laser wavelength of 405 nm. Subsequently, the pattern was developed using a 1:4 mixture of AZ 400K and DI water, followed by a thorough rinsing step using DI water.

The DRIE process was performed using the SPTS Rapier OMEGA LPX system for a duration of 1.25 hrs to fabricate trenches. The dimensions of the trench patterns are as follows: 200 μm, 100 μm, 50 μm, 30 μm, 25 μm, 20 μm, 15 μm, 10 μm, and 5 μm, evenly spaced at intervals of 100 μm. Ar²/C₄ F₈/SF₆/C₄ F₈ corresponding to primary (P)/primary (P)/primary (P)/secondary(S) at flow rates of 200 sccm/200 sccm/1 sccm/120 sccm were used for the plasma strike step, lasting for 1 s at a pressure of 40 m Torr. Primary source 1 operated at a power of 2500 W at 13.56 MHz, while the ICP source 2 operated at 1000 W at 13.50 MHz. The Bosch process comprises a looped sequence involving polymer deposition (Dep), polymer removal (E1), and Si etching (E2). Dep occurs for 1.4 s at a pressure of 45 mTorr without bias, using C₄ F₈/SF₆/C₄ F₈ corresponding to P/P/S at flow rates of 360 sccm/1 sccm/95 sccm, with source 1 at 2500 W and source 2 at 1000 W. E1, lasting for 1.5 s at 25 m Torr, operates with source 1 at 2500 W and source 2 at 1000 W, with ramped low-frequency (LF) bias power from 75 W to 110 W at 150 Hz. This step uses C₄ F₈/SF₆/C₄ F₈ corresponding to P/P/S at flow rates of 1 sccm/300 sccm/1 sccm. E2, executed for 1.9 s at 40 mTorr, utilizes C₄ F₈/SF₆/C₄ F₈ corresponding to P/P/S at flow rates of 1 sccm/400 sccm/1 sccm with source 1 at 2500 W and source 2 at 1000 W at 50 W bias. This cycle is repeated 850 times between Dep and E2, and the substrate temperature is maintained at 19° C. To remove the resist material, a combination of acetone, isopropyl alcohol, and deionized water was used. Any resist remnants were eliminated using a PVA TePla microwave O₂ asher. Subsequently, the samples were loaded into a thermal furnace and held at a temperature of 1100° C. for a duration of 1.5 hr. During this time, an estimated oxide growth of 800 nm occurred [7-9], as calculated using this tool (https://cleanroom.byu.edu/oxidetimecalc). Following this thermal treatment, a buffered oxide etch process was applied. This entire sequence of thermal treatment and oxide etch was repeated once more for the desired results. The trench structures underwent coating using the deposition procedures outlined above.

Following the deposition within the trenches, laser ablation was utilized to selectively eliminate the TiN film from the edges and lips of these trenches [10]. This process was undertaken to establish distinct regions for the purpose of channeling the current through the TiN coated within a series of electrically isolated trenches. The ablation procedure was conducted in an open-air environment using a diode-pumped ytterbium-doped potassium gadolinium tungstate (Yb: KGW) femtosecond laser. The laser operated at a fundamental wavelength of 1028 nm, which was subsequently converted to 343 nm through a harmonic module. The ablation process was carried out using a laser scanning system equipped with a 100 mm focal length telecentric f-Theta lens. A scanning velocity of 500 mm/s was applied, and the focused spot size measured approximately 15 μm, featuring a hatch line overlap of 10 μm and a laser pulse rate of 100 kHz. The combination of the 15 μm spot size and an average power of 1.3 W resulted in a fluence of approximately 7.5 J/cm².

The transition temperature measurements of the PEALD TiN in trenches were conducted using a four wire measurement and a different cryogenic setup. The temperature steadily decreased from approximately 3 K to 100 mK within a 30-minute period. A small radiation shield was used to cover the trenches, preventing 3 K radiation from affecting the film.

### 4. Step Coverage

### Morphological and Compositional Step Coverage

TABLE III
Average percentage of PEALD TiN step coverage for the top,
sidewall, bottom, and bottom corner of Trenches 9, 7, and
1 relative to the field thickness of a 40 nm planar film.

| | | Top | Sidewall | Bottom | Bottom corner |
|---|---|---|---|---|---|
| Trench | Aspect ratio | (%) | (%) | (%) | (%) |
| Trench 9 | 40 | 134 | 136 | 66 | 8.6 |
| Trench 7 | 20 | 128 | 114 | 105 | 79 |
| Trench 1 | 2 | 110 | 119 | 103 | 107 |

TABLE IV
Percentage of PEALD TiN step coverage for the top at positions
1, 2, and 3 as indicated in Fig. S9(a), relative to the field
thickness at position 1 for Trenches 9, 7, and 1, respectively.

| Trench | 1 | 2 | 3 |
|---|---|---|---|
| Trench 9 | 100% | 96% | 156% |
| Trench 7 | 100% | 94% | 125% |
| Trench 1 | 100% | 91% | 135% |

PEALD “Breaking” in 3D Features

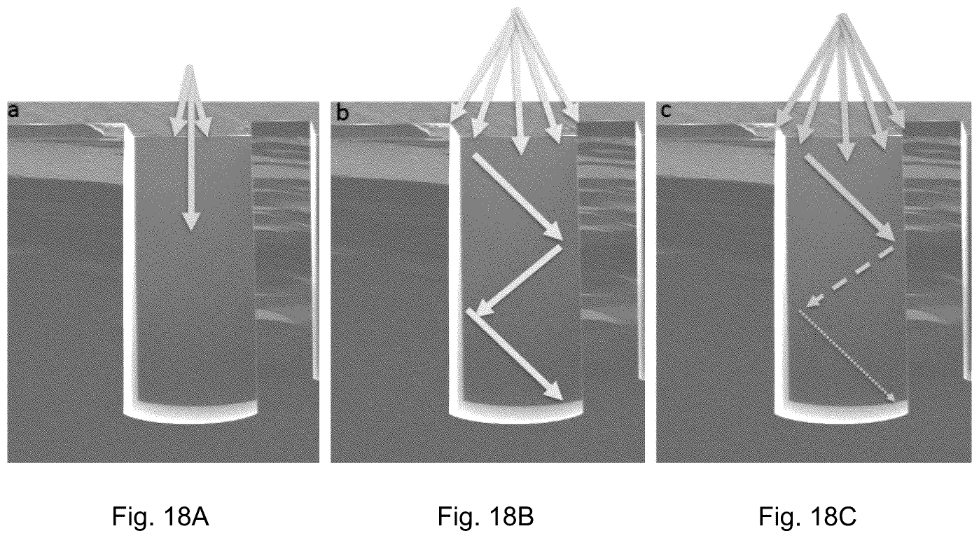

The efficacy of ion and radical transport towards the trench bottom is adversely affected by an increased aspect ratio (AR >10.5). The ion flux (N⁺/Ar⁺) to the sidewall is much less than that to the field and at a glancing angle, predominantly normal to the surface, as illustrated in FIG. 18A. The TDMAT precursor exhibits a cosine distribution, and the flux survives bounces, as depicted in FIG. 18B. Reactive radicals (N*) also follow a cosine distribution, as shown in FIG. 18(c), leading to a decrease in radical flux and subsequent recombination:

$${N}^{*} + {N}_{surface} \to {N}_{2} ( g )$$

Ref [11] suggests that this recombination-limited phenomenon is more pronounced in ARs >10.

In summary, an optimized PEALD technique as described herein deposits high-quality superconducting TiN on planar and 3D trenches with an AR of up to 40. Despite PEALD limitations ³⁹ in trench geometry due to transport restrictions, recombination, radical consumption, and scattering, our study achieves a comparable T_{c} to previous reports in vias. The thickness is significantly reduced (by a factor of >4) compared to thicker films (150-230 nm), elevated process temperatures, or nonPEALD methods ^{2, 11, 12}. We suggest that films >40 nm produced by our process in vias could lead to higher I_{c} and T_{c}, highlighting the importance of ion behavior and the tradeoff between high ARs (>10.5) and morphology/composition. The influence of ion impact orientation and AR on T_{c} is evident, with a breakpoint observed at an AR of 20.

### Advantages and Improvements

Transition metal nitrides, such as TiN, NbN, and NbTiN, possess a high intrinsic kinetic inductance (KI) due to their substantial London penetration depth. This characteristic is crucial in numerous superconducting devices (SDs) utilized across various research fields and technologies, including quantum processors, ² extendedlifetime quantum transduction, ³ highly sensitive photon detection ^{4,5} and spectroscopy, ⁶ and quantum-limited parametric amplification.^{5,7}

Transition metal nitrides, such as TiN, NbN, and NbTiN, possess a high intrinsic kinetic inductance (KI) due to their substantial London penetration depth. This characteristic is crucial in numerous superconducting devices (SDs) used in various research fields, including quantum computing, transduction, photon detection, and parametric amplification. These films play a pivotal role in advancing SDs that exhibit exceptional performance and reliability.

Atomic layer deposition (ALD) offers precise control over film thickness at the atomic level, ensuring exceptional uniformity and conformality on complex 3D structures, making it advantageous compared to traditional reactive sputtering for depositing these superconducting films. Specifically, while traditionally produced TiN films, made using reactive sputtering, boast exceptional purity, ^{4,5} by avoiding unwanted residuals and byproducts, atomic layer deposition (ALD)-deposited TiN films offer improved resistance to pinhole and shadowing effects.⁸

Furthermore, the KI of these superconducting film scales inversely to its thickness. This highlights the critical importance of controlling and achieving a thin-film configuration with uniformity over a large area and high aspect ratios, especially for large arrays requiring consistent superconducting properties and high yield applications. ALD emerges as a viable approach for fabricating such devices, offering precise control over film thickness, uniformity, and large-scale deposition, homogeneity and 3D integration. However, the attainment of high-quality superconducting films via ALD poses significant challenges including the following:
1. Impurities can introduce irregularities that have a detrimental impact on the superconducting properties of the film.
2. The synthesis methods employed for the precursors typically involve complex compounds, necessitating stringent measures to minimize impurities during the deposition process.
3. It is essential to establish a robust and repeatable ALD process that yields impressive superconducting parameters with minimal impurities. This will ensure the effective utilization of high-performance SDs compatible with ALD techniques.

Therefore, it is crucial to achieve and sustain an exceedingly low concentration of impurity content due to the intricate nature of ALD processes. As illustrated herein. The present disclosure reports on deposition of high-quality superconducting TiN films using plasma-enhanced ALD (PEALD) with substrate biasing, maintaining low impurity concentrations and achieving nominal superconducting parameters.

The present disclosure discloses the parameter space for growth conditions of high quality transition metal nitride films. While TiN films produced using halide precursors demonstrate high quality, ^{15, 16, 26-28} tetrakis (dimethylamido) titanium (TDMAT) has shown very limited but promising results at a lower growth temperature (<400° C.). ^{14, 17, 29, 30} Krylov et al. ²⁹ reported an optimized process using TDMAT, and N₂/Ar plasma at low pressure (≈1 mTorr), producing highly crystalline TiN films with a resistivity of ≈100μΩcm. However, these studies did not address step coverage or superconductivity. In contrast, the present disclosure further includes a biased substrate to provide optimized control over ion energy ³¹⁻³³ and film densification. This enables the fabrication of superconducting films with T_{c} comparable to those obtained through reactive sputtering ^{4, 5, 9, 20} and surpasses previously reported ALDdeposited techniques. ^{2, 14, 15, 30, 34} During our experiments, the highest quality film was achieved using N₂/Ar compared to H₂/Ar and NH₃/Ar chemistries (Table I).

### Example Devices Utilizing KI Properties of Superconducting Transition Metal Nitrides

LeDuc et al. ⁴ pioneered highly sensitive arrays of microwave resonators (microresonators) using superconducting TiN films. These microwave kinetic inductance detectors (MKIDs), fabricated through reactive sputtering, showed remarkable sensitivity to dissipation signals. Quasiparticle lifetimes reached 200 μs with internal quality factors (Qᵢ>10⁷) for far-IR, UV, and x-ray photon detection, offering potential sensitivities below 10⁻¹⁹ WHz^{-1/2}. Likewise, kinetic inductance parametric amplifiers (KIPAs),^{1, 5, 7} amplifying signals near the quantum limit for parametric gain, have been realized. In quantum computation, TiN exhibits low-loss microwave properties beneficial for high-coherence qubits. For instance, transmon qubits exhibit coherence times of up to 60 μs on silicon ⁹ and 300 μs on sapphire.¹⁰ Utilizing superconducting TiN-coated through-silicon vias (TSVs) in transition edge sensors with SQUID readouts ¹¹ and quantum processors, characterized by high aspect ratios (ARs) and critical currents, has the potential to alleviate interconnect congestion. This preserves qubit coherence in a 3D architecture, achieving relaxation times of up to 12.5 μs^{2, 12, 13}

For example, in thin films at low temperatures, KI is crucial in high frequency fields, exhibiting dissipation-less nonlinearity driven by electron-phonon interactions. Described by the equation ¹:

$${L}_{k} ( I ) \approx {L}_{k} ( 0 ) [ 1 + {( \frac{I}{{I}_{*}} )}^{2} ] \qquad ( 1 )$$

I_{*} characterizes nonlinearity on the order of the critical current, and Lₖ (0) is the linear kinetic inductance at low power, approximated by the sheet inductance L_{□} with a geometric factor γ, where Lₖ (I)=γL_{□}. According to the Mattis-Bardeen theory, ^{1,24} L_{□} at low frequencies and T=0 is given by:

$${L}_{□} = \frac{ℏ {R}_{□}}{π Δ} \qquad ( 2 )$$

R_{□} is the normal-state sheet resistance, and Δ denotes the superconducting band gap, where 2Δ=3.5k_{B}T_{c}. When incident photons surpass the energy threshold, they are absorbed into the material, momentarily breaking Cooper pairs. TiN, with a higher KI fraction, ⁴ allows for extended quasiparticle recombination times at a lower material volume compared to Al²⁵ Evidently, T_{c} and L_{□} are crucial for characterizing nonlinear KI-based superconducting devices (SDs).

However, film thickness inversely correlates with KI, ¹ posing challenges for scaling superconducting properties, especially near the thin film limit with sputtering. ALD is a potential solution, but faced limitations as described herein. ^{2,14-17} High process temperatures may create large amorphous interfacial layers, introducing twolevel systems (TLS), ^{18,19} causing high microwave losses and reduced Qᵢ. Loss mechanisms vary based on design rules, ²⁻²³ within interfacial layers, material surfaces, or both. However, the methods described herein overcome these challenges by providing a reliable ALD process at lower temperatures while preserving superconducting properties. Films fabricated according to the methods described herein can enhance performance of devices that utilize the KI properties of transition metal nitride films.

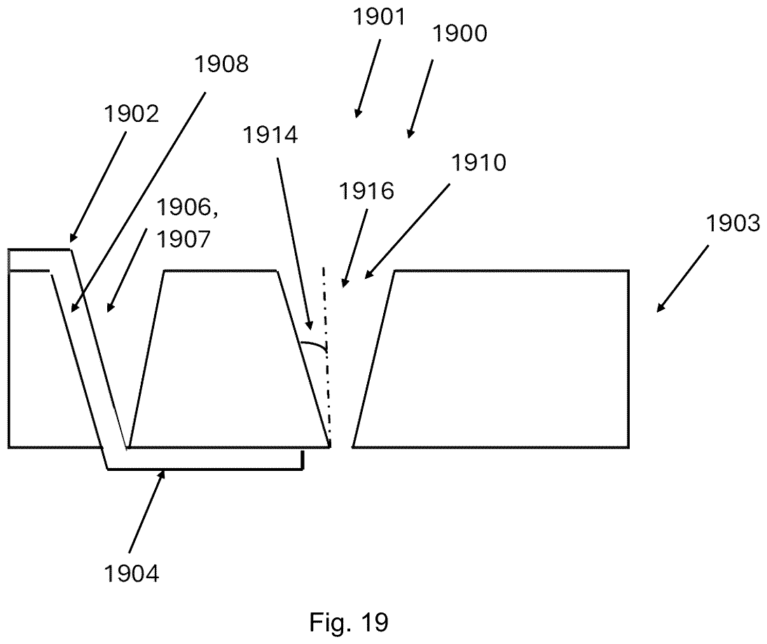

FIG. 19 illustrates device 1900 comprising an interconnect 1901 between a first metallization 1902 on a first surface of a substrate 1903, a second metallization 1904 on a second surface of the substrate. The interconnect comprises a via 1906 comprising a third metallization 1907 on a sidewall 1908 of an opening 1910 through the substrate positioned so as to electrically connect the first metallization to the second metallization. The sidewall 1908 is inclined (e.g., at an angle 1914 greater than 1 degree, e.g., in a range of 30-60 degrees or in a range of 1-60 degrees) with respect to a normal/vertical direction 1916 through the thickness of the substrate.

The third metallization comprises or consists of a thickness of 100 nm or less of the transition metal nitride having a crystal quality such that the transition metal nitride film has critical temperature (for transition to superconductive properties) of no less than 2 K.

The second and/or third metallization comprises or consists of a thickness of 200 nm or less of the transition metal nitride having a crystal quality such that the transition metal nitride film has critical temperature (for transition to superconductive properties) of no less than 5 K.

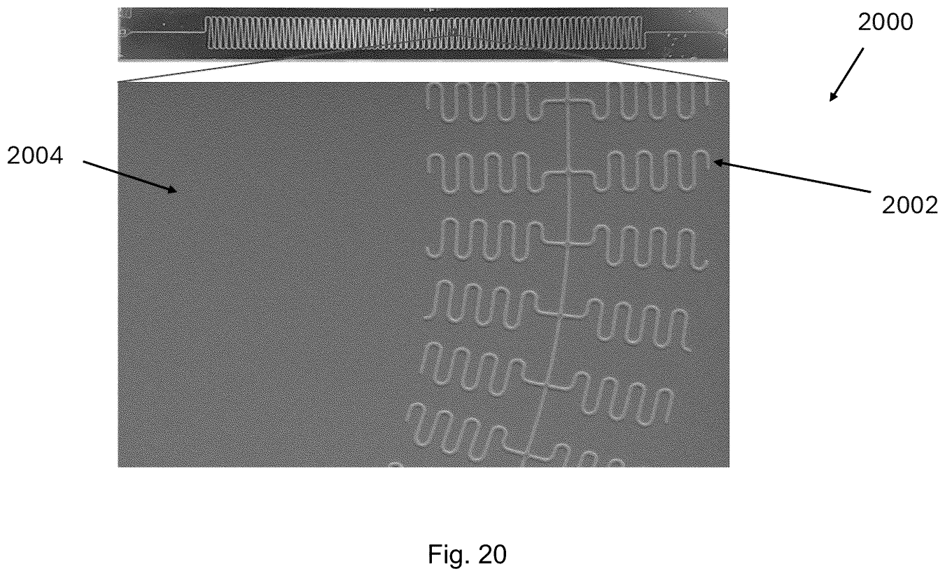

FIG. 20 illustrates a kinetic inductance parametric amplifier (KIPA) 2000 whose transition metal nitride layers 2002 were deposited on a silicon substrate 2004 using the PEALD as described herein.

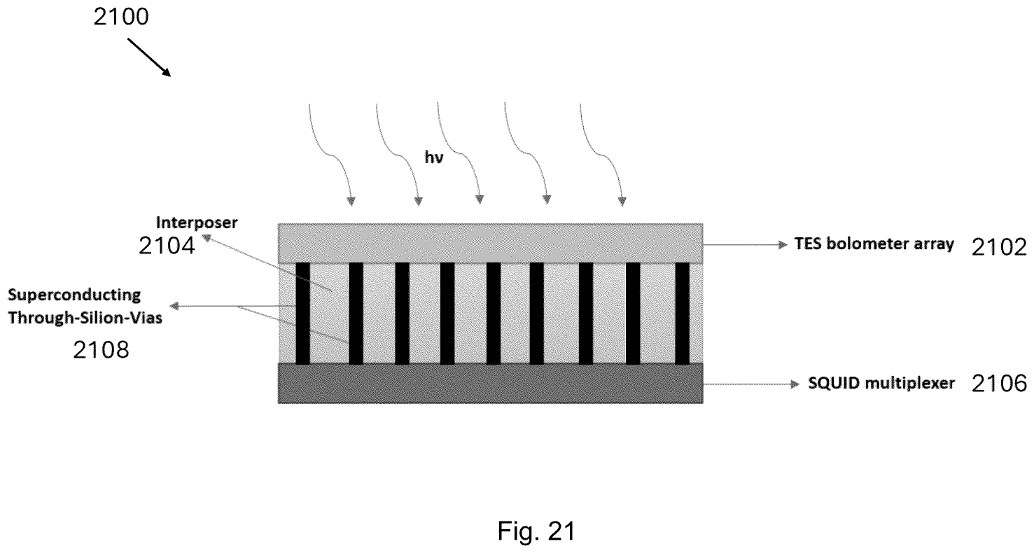

FIG. 21 is a schematic illustration of a proposed Transition Edge Sensor (TES) 2100 whose superconducting layers (comprising transition metal nitride) could be deposited using PEALD as described herein. The device comprises TES bolometer array 2102 (comprising transition metal nitride) on a first side of a substrate/interposer 2104 (e.g., silicon); a SQUID multiplexer 2106 (comprising transition metal nitride) on a second side of the substrate 2104; and vias 2108 comprising transition nitride through the substrate to connect the bolometer array to the multiplexer. The via can have inclined sidewalls as shown in FIG. 19. The bolometer array is positioned for receiving electromagnetic radiation hv.

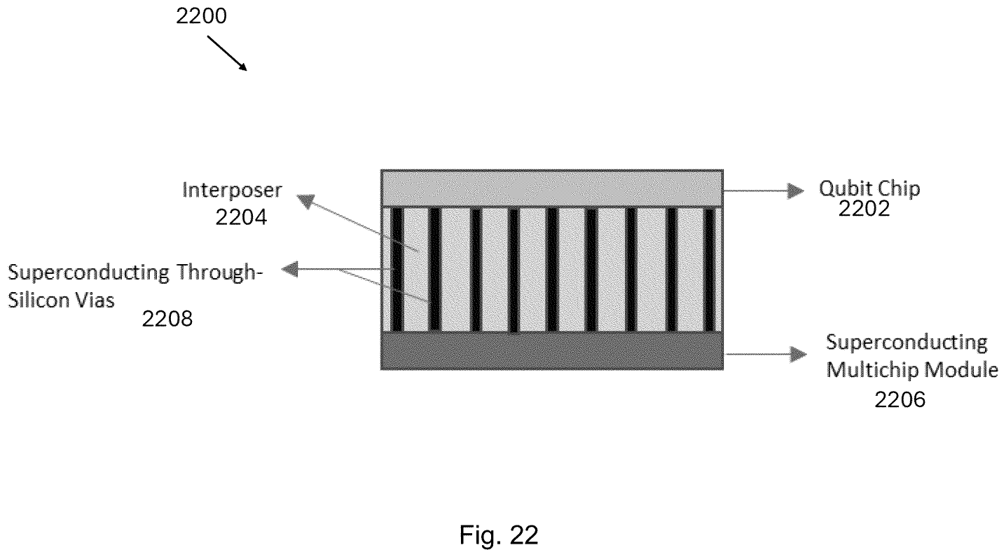

FIG. 22 is a schematic of a proposed quantum processor 2200 whose superconducting layers (comprising transition metal nitride) could be deposited using PEALD as described herein. The device comprises qubit chip 2102 (comprising transition metal nitride) on a first side of a substrate/interposer 2204 (e.g., silicon); a superconducting multichip module 2206 (comprising transition metal nitride) on a second side of the substrate 2204; and one or more vias 2208 comprising transition nitride through the substrate to connect the bolometer array to the multiplexer. The via can have inclined sidewalls as shown in FIG. 19.

### Example Applications

Superconducting devices (SDs) play a crucial role in addressing fundamental challenges across various fields, including dark matter research, exoplanet transit spectroscopy, astronomy, cosmology, quantum computing and information processing, and biological imaging. These devices encompass a range of technologies such as superconducting nanowire single-photon detectors (SNSPDs), microwave kinetic inductance devices (MKIDs), parametric amplifiers, qubits, and kinetic inductance parametric up-converters (KPUPs). Their significance extends to investigating the earliest light emissions after the Big Bang approximately 14 billion years ago and enabling deep space communication.

The Microdevices Laboratory (MDL) at JPL has been at the forefront of developing and utilizing these technologies, exemplified by their involvement in projects such as the Deep Space Optical Communication (DSOC) project, the Terahertz Intensity Mapper (TIM) balloon experiment, the Galaxy Evolution Probe (GEP) for integral field spectroscopy, the Background Imaging of Cosmic Extragalactic Polarization (BICEP) telescopes, and the Keck Array.

In this context, the ALD technology we have developed provides an alternative and reliable method for producing high quality films, which is especially valuable considering the scarcity of certain high-quality sputtering targets. ALD is expected to offer more uniform films compared to traditional sputtering methods, a critical factor for large-scale detector arrays spanning centimeter scales. This improved uniformity can significantly increase the absolute detector yield on each wafer, making ALD an attractive option for achieving higher performance and efficiency in SDs.

### Device and Method Embodiments

1. A method of depositing a transition nitride film, comprising:
depositing the film on a substrate using plasma enhanced atomic layer deposition, comprising:
performing a number of deposition cycles in an atmosphere comprising no hydrogen or less than 1% hydrogen, or hydrogen containing gases the deposition cycles each comprising:
   a precursor cycle exposing a substrate to a precursor to form a precursor treated substrate;
   a plasma cycle exposing the precursor treated substrate to plasma formed using an inductively coupled plasma source; and
   applying a radio frequency (RF) bias to the substrate during a final/last portion of the plasma cycle to accelerate ions in the plasma onto the substrate; and
so that a film comprising a transition metal nitride is made.
2. The method of example 1, wherein the precursor comprises a gas comprising:
tetrakis (dimethylamide) titanium (TDMAT) for the film comprising titanium nitride, or
(tert-butylimido)tris(diethylamido)niobium(V) (TBTDEN) or (tert-butylimido)tris(methylethylamido)niobium(V) (TBTMEN) for the film comprising NbN, or
Tetrakis(ethylmethylamido) vanadium for the film comprising VN, or
chlorides or fluorides of the transition metal (e.g., titanium, vanadium, or niobium) being used to synthesize the transition metal nitride, e.g., TiCl₄, TiCl₅, VCl₄, VCl₅, NbCl₄, NbCl₅.
3. The method of example 1 or 2, wherein the transition metal nitride comprises or is, or consists of, or consists essentially of titanium nitride (TiN), niobium nitride (NbN), NbTiN, vanadium nitride (VN), or alloys thereof.
4. The method of any of the examples 1-3, wherein the number of cycles is repeated until the film has a thickness in a range of 40-200 nm or a bulk thickness.
5. The method of any of the examples 1-4, wherein the precursor cycle has a duration less than 1 second, and/or the plasma cycle has a duration of at least 20 seconds and/or the RF bias is applied for at last the last 10 seconds of the plasma half cycle.
6. The method of any of the examples 1-5, wherein the plasma is, comprises, or consists of, or consists essentially of argon ions in a nitrogen atmosphere.
7. The method of any of the examples 1-6, further comprising performing the deposition cycles using a pressure in the reaction chamber of 0.022 Torr or less (or 0.03 Torr or less, 0.1 Torr or less, or 100 mTorr or less, or 0.8 Torr or less) for the precursor cycle and 0.003 Torr or less (or 0.005 Torr or less, or 0.01 Torr or less, or 100 mTorr or less, or 10 mTorr or less, or 0.8 Torr or less) for the plasma cycle.
8. The method of any of the examples 1-7, wherein the substrate comprises three dimensional (3D) structures having an aspect ratio of at least 40 and the film is deposited conformally on the 3D structures and/or the substrate is float zone silicon with less than 10 particles having a diameter greater than 0.3 microns.
9. The method of any of the examples 1-8, further comprising selecting an angle of incidence (e.g., 30-60 degrees with respect to a vertical direction) or angular distribution of the ions (incident on the substrate) that increases a crystalline quality of the film and increases a critical temperature of no less than 1.9 Kelvin (K) (e.g., Tc in a range of 1.9-20 K) for transitioning to a superconducting state/property of the film.
10. The method of any of the examples 1-9, wherein the superconducting properties are characterized by the film of thickness 40 nm having a critical temperature of no less than 4.35 Kelvin (K) or the film of thickness of 200 nm or less having the critical temperature of no less than 1.9 Kelvin (or critical temperature T_{c} in a range of 1.9-20K).
11. The method of any of the examples 1-10, wherein the film is deposited on a substrate comprising trenches, the method further comprising:
performing a laser ablation and/or laser cleaving of the film along edges and lips of the trenches to ensure that superconducting properties of the transition metal nitride are extracted within the trenches while bypassing lower-resistance planar regions of the transition metal nitride; and/or
using laser trimming (e.g., cleaving or ablation) to isolate different regions of a semiconductor or superconductor device comprising two dimensional and/or three dimensional structures (e.g., with a spatial resolution that is higher as compared to, and/or to pattern inside vias or trenches that are inaccessible to, conventional lithography
12. The method of any of the examples 1-11, further comprising performing a preconditioning step comprising at least 10 repeats of a cycle comprising a precursor exposure and a plasma exposure.
13. An apparatus 200 for performing plasma enhanced atomic layer deposition, comprising:
   a reaction chamber 202 comprising a precursor inlet 204; a plasma inlet 206; and an outlet 208;
   a substrate table or holder 210 for supporting a substrate 212 in the reaction chamber;
   a precursor source 214 coupled to the precursor inlet for inputting a precursor to the reaction chamber;
   an plasma source (e.g., but not limited to, an inductively coupled plasma source 216 e.g., comprising a sapphire tube 216a) coupled to the plasma inlet to the reaction chamber;
   a gas source 217 for supplying a hydrogen free atmosphere (e.g., 100% argon and nitrogen) into the inductively coupled plasma source via plasma gas lines 217a;
   a pump 218 coupled to the outlet for reducing pressure in the reaction chamber;
   an RF bias source 220 coupled to the substrate table for biasing a substrate with an RF bias; and
a computer 222 or computer system coupled to the precursor source, the RF bias source, the pump; and the plasma source, the computer configured to instruct the apparatus to perform a number of deposition cycles each comprising:
   a precursor cycle exposing the substrate to the precursor (e.g., at a pressure below 220 mTorr or 200 mTorr) to form a precursor treated substrate;
   a plasma cycle exposing the precursor treated substrate to the plasma (e.g., at a pressure below 3 mTorr or below 10 mTorr or below 100 mTorr); and
   applying the RF bias to the substrate during a final portion of the plasma cycle.
14. A film comprising:
a planar titanium nitride 300, 1000 deposited by atomic layer deposition (e.g., on a substrate or wafer, e.g., silicon) and exhibiting properties as characterized by
a resistivity and a thickness varying by less than 2% over an entirety of an area of the film; and
superconductivity at a critical temperature of no less than 1.9 Kelvin (e.g., T_{c} critical temperature in a range of 1.9 K-20 K, 1.9 K≤Tc≤20 K)) over an entirety of the area A of the film having a thickness less than 200 nm (e.g., 4.35 K over an entirety of the area with a 40 nm film, and no less than 4.5 K over an entirety of the area with an 80 nm film).
15. The film of example 14, wherein the area is greater than or equal to a circular area having
   a diameter of at least 6 inches.
16. The film of example 14 or 15 having the thickness in a range of 40-100 nm.
17. The film of any of the examples 14-16, wherein the film has the resistivity ρ above 70 μΩ*cm.
18. The film of any of the examples 14-17, wherein the film is conformal to a surface of the substrate having an aspect ratio of at least 40 and the critical temperature of no less than 2K.
19. A device 1900 comprising an interconnect 1901 between a first metallization 1902 on a first surface of a substrate 1903, a second metallization 1904 on a second surface of the substrate; and one or more vias 1906 comprising a third metallization 1907 through the substrate connecting the first metallization to the second metallization. The via comprises a sidewall 1908 that is inclined with respect to a vertical direction 1916 through the substrate. The third metallization comprises a thickness of 100 nm or less of the transition metal nitride film having the critical temperature of no less than 1.9 K (e.g., in a range of 1.9K-20K). The first metallization, the second metallization, and the third metallization comprise or consist of transition metal nitride having a critical temperature (and corresponding crystal quality) for transitioning to the superconducting state, e.g., of no less than 5K or no less than 1.9 K or in a range of 1.9K-20K.
20. A device comprising the film of any of the examples 1-19 and utilizing a kinetic inductance of the film.
21. The device of any of the examples 19 or 20, comprising a superconducting resonator, a quantum circuit, a qubit, a microwave kinetic inductance detector (MKIDs), a kinetic inductance parametric amplifiers (KIPAs), or superconducting nanowire single photon detectors (SNSPDs).
22. The apparatus of example 13, wherein the computer comprises:
   (a) one or more computers having one or more memories;
   (b) one or more processors executing on the one or more computers;
   (c) the one or more memories storing one or more sets of instructions,
      wherein the one or more sets of instructions, when executed by the one or more processors cause the one or more processors to perform operations comprising configured to instruct the apparatus to perform the number of deposition cycles.
23. The apparatus of example 13 or 22 configured to perform the method of any of the examples 1-12.
24. The film or device of any of the examples 14-21 wherein the transition metal nitride is deposited using the method or apparatus of any of the examples 1-13 and 22.
25. The film or device of any of the examples 14-21 or 24 wherein the transition metal nitride is deposited on/in one or more vias or trenches having a controlled aspect ratio selected to control the orientation of the surface presented to the ions or grain size and/or critical temperature and/or film quality of the transition metal nitride film deposited in the trench or vias. For example, the aspect ratio (e.g., diameter/area/size of the top opening of the trench or via is different (e.g., wider or larger) as compared to the size of the base or opening at the base of the trench or via) so as to determine/control the angle at which the ions are incident on the substrate in the trench/via, thereby controlling the crystal quality of the film and the critical temperature of the film.
26. The film or device of example 25, wherein the via or trenches have a cross-section comprising a cone or inverted cone or wedge, wherein the size of the opening at the bottom and top of the trench or opening are different (e.g., larger at the top surface closest the ion source).
27. The film or device or method of any of the examples 1-26, wherein the critical temperature Tc (for transition to superconducting state) is in a range of 1.9K-20 K (1.9K ≤Tc≤20K), e.g., where the higher Tc of 20K is possible for at least NbN.
28. The film or device or method of any of the examples 1-27, wherein the critical temperature is Tc, the temperature at which the transition metal nitride becomes superconducting.

### Hardware Environment

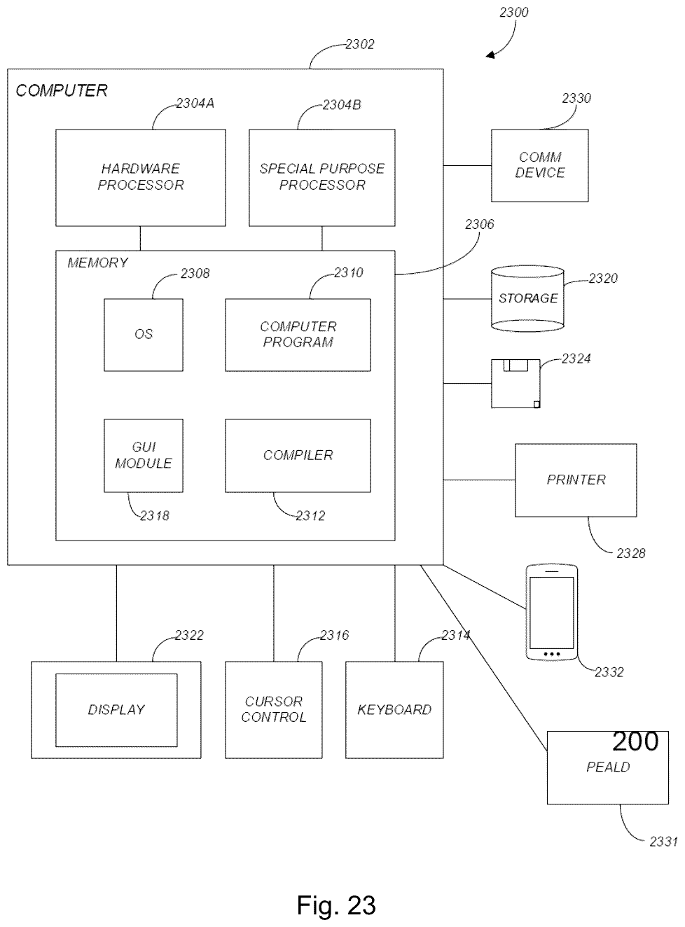

FIG. 23 is an exemplary hardware and software environment 2300 (referred to as a computer-implemented system and/or computer-implemented method) used to implement one or more embodiments of the invention to control the PEALD 2331, 200 system. The hardware and software environment includes a computer 2302 and may include peripherals. Computer 2302 may be a user/client computer, server computer, or may be a database computer. The computer 2302 comprises a hardware processor 2304A and/or a special purpose hardware processor 2304B (hereinafter alternatively collectively referred to as processor 2304) and a memory 2306, such as random access memory (RAM). The computer 2302 may be coupled to, and/or integrated with, other devices, including input/output (I/O) devices such as a keyboard 2314, a cursor control device 2316 (e.g., a mouse, a pointing device, pen and tablet, touch screen, multi-touch device, etc.) and a printer 2328. In one or more embodiments, computer 2302 may be coupled to, or may comprise, a portable or media viewing/listening device 2332 (e.g., an MP3 player, IPOD, NOOK, portable digital video player, cellular device, personal digital assistant, etc.). In yet another embodiment, the computer 2302 may comprise a multi-touch device, mobile phone, gaming system, internet enabled television, television set top box, or other internet enabled device executing on various platforms and operating systems.

In one embodiment, the computer 2302 operates by the hardware processor 2304A performing instructions defined by the computer program 2310 (e.g., a computer-aided PEALD application) under control of an operating system 2308. The computer program 2310 and/or the operating system 2308 may be stored in the memory 2306 and may interface with the user and/or other devices to accept input and commands and, based on such input and commands and the instructions defined by the computer program 2310 and operating system 2308, to provide output and results.

Output/results may be presented on the display 2322 or provided to another device for presentation or further processing or action. In one embodiment, the display 2322 comprises a liquid crystal display (LCD) having a plurality of separately addressable liquid crystals. Alternatively, the display 2322 may comprise a light emitting diode (LED) display having clusters of red, green and blue diodes driven together to form full-color pixels. Each liquid crystal or pixel of the display 2322 changes to an opaque or translucent state to form a part of the image on the display in response to the data or information generated by the processor 2304 from the application of the instructions of the computer program 2310 and/or operating system 2308 to the input and commands. The image may be provided through a graphical user interface (GUI) module 2318. Although the GUI module 2318 is depicted as a separate module, the instructions performing the GUI functions can be resident or distributed in the operating system 2308, the computer program 2310, or implemented with special purpose memory and processors.

In one or more embodiments, the display 2322 is integrated with/into the computer 2302 and comprises a multi-touch device having a touch sensing surface (e.g., track pod or touch screen) with the ability to recognize the presence of two or more points of contact with the surface. Examples of multi-touch devices include mobile devices (e.g., IPHONE, NEXUS S, DROID devices, etc.), tablet computers (e.g., IPAD, HP TOUCHPAD, SURFACE Devices, etc.), portable/handheld game/music/video player/console devices (e.g., IPOD TOUCH, MP3 players, NINTENDO SWITCH, PLAYSTATION PORTABLE, etc.), touch tables, and walls (e.g., where an image is projected through acrylic and/or glass, and the image is then backlit with LEDs).

Some or all of the operations performed by the computer 2302 according to the computer program 2310 instructions may be implemented in a special purpose processor 2304B. In this embodiment, some or all of the computer program 2310 instructions may be implemented via firmware instructions stored in a read only memory (ROM), a programmable read only memory (PROM) or flash memory within the special purpose processor 2304B or in memory 2306. The special purpose processor 2304B may also be hardwired through circuit design to perform some or all of the operations to implement the present invention. Further, the special purpose processor 2304B may be a hybrid processor, which includes dedicated circuitry for performing a subset of functions, and other circuits for performing more general functions such as responding to computer program 2310 instructions. In one embodiment, the special purpose processor 2304B is an application specific integrated circuit (ASIC).

The computer 2302 may also implement a compiler 2312 that allows an application or computer program 2310 written in a programming language such as C, C++, Assembly, SQL, PYTHON, PROLOG, MATLAB, RUBY, RAILS, HASKELL, or other language to be translated into processor 2304 readable code. Alternatively, the compiler 2312 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 2310 accesses and manipulates data accepted from I/O devices and stored in the memory 2306 of the computer 2302 using the relationships and logic that were generated using the compiler 2312.

The computer 2302 also optionally comprises an external communication device such as a modem, satellite link, Ethernet card, or other device for accepting input from, and providing output to, other computers 2302.

In one embodiment, instructions implementing the operating system 2308, the computer program 2310, and the compiler 2312 are tangibly embodied in a non-transitory computer-readable medium, e.g., data storage device 2320, which could include one or more fixed or removable data storage devices, such as a zip drive, floppy disc drive 2324, hard drive, CD-ROM drive, tape drive, etc. Further, the operating system 2308 and the computer program 2310 are comprised of computer program 2310 instructions which, when accessed, read and executed by the computer 2302, cause the computer 2302 to perform the steps necessary to implement and/or use the present invention or to load the program of instructions into a memory 2306, thus creating a special purpose data structure causing the computer 2302 to operate as a specially programmed computer executing the method steps described herein. Computer program 2310 and/or operating instructions may also be tangibly embodied in memory 2306 and/or data communications devices 2330, thereby making a computer program product or article of manufacture according to the invention. As such, the terms “article of manufacture,” “program storage device,” and “computer program product,” as used herein, are intended to encompass a computer program accessible from any computer readable device or media.

Of course, those skilled in the art will recognize that any combination of the above components, or any number of different components, peripherals, and other devices, may be used with the computer 2302.

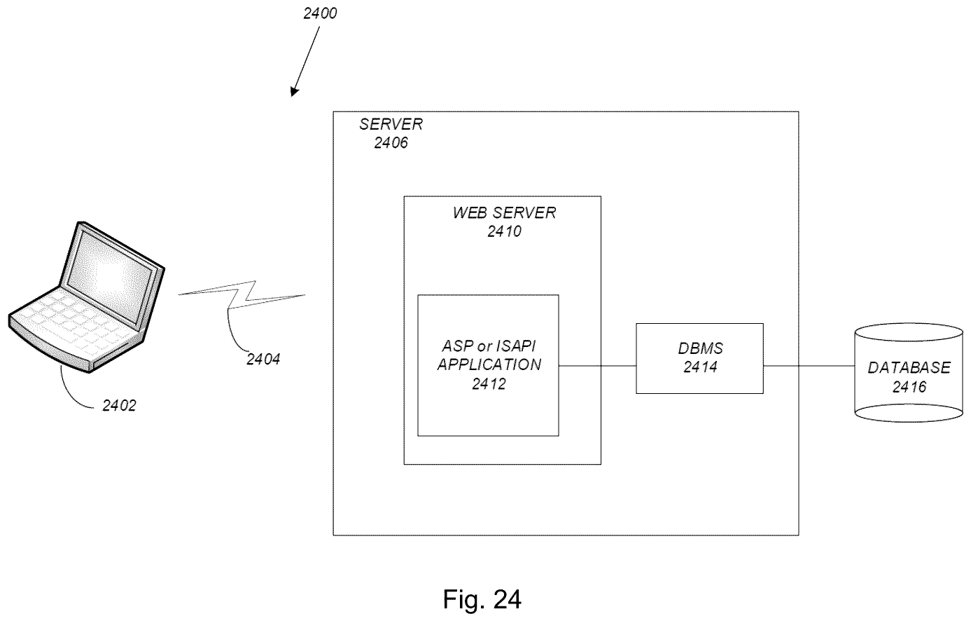

FIG. 24 schematically illustrates a typical distributed/cloud-based computer system 2400 using a network 2404 to connect client computers 2402 to server computers 2406. A typical combination of resources may include a network 2404 comprising the Internet, LANs (local area networks), WANs (wide area networks), SNA (systems network architecture) networks, or the like, clients 2402 that are personal computers or workstations (as set forth in FIG. 23), and servers 2406 that are personal computers, workstations, minicomputers, or mainframes (as set forth in FIG. 23). However, it may be noted that different networks such as a cellular network (e.g., GSM [global system for mobile communications] or otherwise), a satellite based network, or any other type of network may be used to connect clients 2402 and servers 2406 in accordance with embodiments of the invention.

A network 2404 such as the Internet connects clients 2402 to server computers 2406. Network 2404 may utilize ethernet, coaxial cable, wireless communications, radio frequency (RF), etc. to connect and provide the communication between clients 2402 and servers 2406. Further, in a cloud-based computing system, resources (e.g., storage, processors, applications, memory, infrastructure, etc.) in clients 2402 and server computers 2406 may be shared by clients 2402, server computers 2406, and users across one or more networks. Resources may be shared by multiple users and can be dynamically reallocated per demand. In this regard, cloud computing may be referred to as a model for enabling access to a shared pool of configurable computing resources.

Clients 2402 may execute a client application or web browser and communicate with server computers 2406 executing web servers 2410. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 2402 may be downloaded from server computer 2406 to client computers 2402 and installed as a plug-in or ACTIVEX control of a web browser. Accordingly, clients 2402 may utilize ACTIVEX components/component object model (COM) or distributed COM (DCOM) components to provide a user interface on a display of client 2402. The web server 2410 is typically a program such as MICROSOFT'S INTERNET INFORMATION SERVER.

Web server 2410 may host an Active Server Page (ASP) or Internet Server Application Programming Interface (ISAPI) application 2412, which may be executing scripts. The scripts invoke objects that execute business logic (referred to as business objects). The business objects then manipulate data in database 2416 through a database management system (DBMS) 2414. Alternatively, database 2416 may be part of, or connected directly to, client 2402 instead of communicating/obtaining the information from database 2416 across network 2404. When a developer encapsulates the business functionality into objects, the system may be referred to as a component object model (COM) system. Accordingly, the scripts executing on web server 2410 (and/or application 2412) invoke COM objects that implement the business logic. Further, server 2406 may utilize MICROSOFT'S TRANSACTION SERVER (MTS) to access required data stored in database 2416 via an interface such as ADO (Active Data Objects), OLE DB (Object Linking and Embedding DataBase), or ODBC (Open DataBase Connectivity).

Generally, these components 2400-2416 all comprise logic and/or data that is embodied in/or retrievable from device, medium, signal, or carrier, e.g., a data storage device, a data communications device, a remote computer or device coupled to the computer via a network or via another data communications device, etc. Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 2402 and 2406 may be interchangeable and may further include thin client devices with limited or full processing capabilities, portable devices such as cell phones, notebook computers, pocket computers, multi-touch devices, and/or any other devices with suitable processing, communication, and input/output capability.

Of course, those skilled in the art will recognize that any combination of the above components, or any number of different components, peripherals, and other devices, may be used with computers 2402 and 2406. Embodiments of the invention are implemented as a software/PEALD application on a client 2402 or server computer 2406. Further, as described above, the client 2402 or server computer 2406 may comprise a thin client device or a portable device that has a multi-touch-based display.

### REFERENCES

The following references are incorporated by reference herein.

### REFERENCES FOR SECTION 1

¹ J. Zmuidzinas, Annu. Rev. Condens. Matter Phys. 3, 169-214 (2012).
² K. Grigoras, N. Yurttagül, J. Kaikkonen, E. Mannila, P. Eskelinen, D. Lozano, H. Li, M. Rommel, D. Shiri, N. Tiencken, S. Simbierowicz, A. Ronzani, J. Hätinen, D. Datta, V. Vesterinen, L. Grönberg, J. Biznárová, A. Roudsari, S. Kosen, A. Osman, M. Prunnila, J. Hassel, J. Bylander, and J. Govenius, IEEE Trans. Quantum Eng. 3, 1-10 (2022).
³ A. Bozkurt, H. Zhao, C. Joshi, H. LeDuc, P. Day, and M. Mirhosseini, Nat. Phys. 19, 1326-1332 (2023).
⁴ H. Leduc, B. Bumble, P. Day, B. Eom, J. Gao, S. Golwala, B. Mazin, S. McHugh, A. Merrill, D. Moore, O. Noroozian, A. Turner, and J. Zmuidzinas, Appl. Phys. Lett. 97, 102509 (2010)
⁵ J. Gao, M. Vissers, M. Sandberg, D. Li, H. Cho, C. Bockstiegel, B. Mazin, H. Leduc, S. Chaudhuri, D. Pappas, and K. Irwin, J. Low Temp. Phys. 176, 136-141 (2014)
⁶ E. Shirokoff, P. Barry, C. Bradford, G. Chattopadhyay, P. Day, S. Doyle, S. Hailey-Dunsheath, M. Hollister, A. Kovács, C. McKenney, H. Leduc, N. Llombart, D. Marrone, P. Mauskopf, R. O'Brient, S. Padin, T. Reck, L. Swenson, and J. Zmuidzinas, SPIE 8452, 209 (2012).
⁷ B. Eom, P. Day, H. LeDuc, and J. Zmuidzinas, Nat. Phys. 8, 623-627 (2012).
⁸ M. Leskelä and M. Ritala, Angew. Chem. Int. Ed. 42, 5548-5554 (2003).
⁹ J. Chang, M. Vissers, A. Corcoles, M. Sandberg, J. Gao, D. Abraham, J. Chow, J. Gambetta, M. Rothwell, G. Keefe, M. Steffen, and D. Pappas, Appl. Phys. Lett. 103, 012602 (2013).
¹⁰ H. Deng, Z. Song, R. Gao, T. Xia, F. Bao, X. Jiang, H. Ku, Z. Li, X. Ma, J. Qin, H. Sun, C. Tang, T. Wang, F. Wu, W. Yu, G. Zhang, X. Zhang, J. Zhou, X. Zhu, Y. Shi, H. Zhao, and C. Deng, Phys. Rev. Applied 19, 024013 (2023).
¹¹ C. Jhabvala, D. Benford, R. Brekosky, M. Chang, N. Costen, A. Datesman, G. Hilton, K. Irwin, A. Kogut, J. Lazear, E. Leong, S. Maher, T. Miller, S. Moseley, E. Sharp, J. Staguhn, and E. Wollack, SPIE 9153, 1038 (2014).
¹² J. Mallek, D. Yost, D. Rosenberg, J. Yoder, G. Calusine, M. Cook, R. Das, A. Day, E. Golden, D. Kim, J. Knecht, B. Niedzielski, M. Schwartz, A. Sevi, C. Stull, W. Woods, A. Kerman, and W. Oliver, arXiv preprint: 2103.08536 (2021).
¹³ T. Hazard, W. Woods, D. Rosenberg, R. Das, C. Hirjibehedin, D. Kim, J. Knecht, J. Mallek, A. Melville, B. Niedzielski, K. Serniak, K. Sliwa, D. Yost, J. Yoder, W. Oliver, and M. Schwartz, Appl. Phys. Lett. 123, 154004 (2023).
¹⁴ A. Shearrow, G. Koolstra, S. Whiteley, N. Earnest, P. Barry, F. Heremans, D. Awschalom, E. Shirokoff, and D. Schuster, Appl. Phys. Lett. 113, 212601 (2018).
¹⁵ P. Coumou, M. Zuiddam, E. Driessen, P. de Visser, J. Baselmans, and T. Klapwijk, IEEE Trans. Appl. Supercond. 23, 7500404-7500404 (2012).
¹⁶ E. Driessen, P. Coumou, R. Tromp, P. de Visser, and T. Klapwijk, Phys. Rev. Lett. 109, 107003 (2012).
¹⁷ D. Morozov, S. Doyle, A. Banerjee, T. Brien, D. Hemakumara, I. Thayne, K. Wood, and R. Hadfield, J. Low Temp. Phys. 193, 196-202 (2018).
¹⁸ W. Phillips, J. Low Temp. Phys. 7, 351-360 (1972).
¹⁹ C. Müller, J. Cole, and J. Lisenfeld, Rep. Prog. Phys. 82, 124501 (2019).
²⁰ M. Vissers, J. Gao, D. Wisbey, D. Hite, C. Tsuei, A. Corcoles, M. Steffen, and D. Pappas, Appl. Phys. Lett. 97, 232509 (2010).
²¹ J. Gao, M. Daal, A. Vayonakis, S. Kumar, J. Zmuidzinas, B. Sadoulet, B. Mazin, P. Day, and H. Leduc, Appl. Phys. Lett. 92, 152505 (2008).
²² W. Woods, G. Calusine, A. Melville, A. Sevi, E. Golden, D. Kim, D. Rosenberg, J. Yoder, and W. Oliver, Phys. Rev. Applied 12, 014012 (2019).
²³ K. Amin, C. Ladner, G. Jourdan, S. Hentz, N. Roch, and J. Renard, Appl. Phys. Lett. 120, 164001 (2022).
²⁴ D. Mattis and J. Bardeen, Phys. Rev. 111, 412 (1958).
²⁵ P. Day, H. LeDuc, B. Mazin, A. Vayonakis, and J. Zmuidzinas, Nature 425, 817-821 (2003).
²⁶ K. Elers, J. Winkler, K. Weeks, and S. Marcus, J. Electrochem. Soc. 152 G589 (2005).
²⁷ S. Heil, J. van Hemmen, C. Hodson, N. Singh, J. Klootwijk, F. Roozeboom, M. van de Sanden, and W. Kessels, J. Vac. Sci. Technol. A 25, 1357-1366 (2007).
²⁸ C. Kuo, A. Mcleod, P. Lee, J. Huang, H. Kashyap, V. Wang, S. Yun, Z. Zhang, J. Spiegelman, R. Kanjolia, M. Moinpour, and A. Kummel, ACS Appl. Electronic Materials 5, 4094-4102 (2023).
²⁹ I. Krylov, E. Zoubenko, K. Weinfeld, Y. Kauffmann, X. Xu, D. Ritter, and M. Eizenberg, J. Vac. Sci. Technol. A 36, 051505 (2018).
³⁰ A. Hossain, H. Wang, D. Catherall, M. Leung, H. Knoops, J. Renzas, and A. Minnich, J. Vac. Sci. Technol. A 41, 062601 (2023).
³¹ T. Faraz, H. Knoops, M. Verheijen, C. van Helvoirt, S. Karwal, A. Sharma, V. Beladiya, A. Szeghalmi, D. Hausmann, J. Henri, M. Creatore, and W. Kessels, ACS Appl. Mater. Interfaces 10, 13158-13180 (2018).
³² C. Lennon, Y. Shu, J. Brennan, D. Namburi, V. Varghese, D. Hemakumara, L. Longchar, S. Srinath, and R. Hadfield, Mater. Quantum Technol. 3 045401 (2023).
³³ S. Peeters, C. Lennon, M. Merkx, R. Hadfield, W. Kessels, M. Verheijen, and H. Knoops, Appl. Phys. Lett. 123, 132603 (2023).
³⁴ A. Torgovkin, S. Chaudhuri, J. Malm, T. Sajavaara, and I. Maasilta, IEEE Trans. Appl. Supercond. 25, 1-4 (2014).
³⁵ S. Ohya, B. Chiaro, A. Megrant, C. Neill, R. Barends, Y. Chen, J. Kelly, D. Low, J. Mutus, P. O'Malley, and P. Roushan, Supercond. Sci. Technol. 27, 015009 (2013).
³⁶ S. Shermukhamedov, L. Chen, R. Nazmutdinov, A. Kaiser, and M. Probst, Nucl. Fusion 61, 086013 (2021).
³⁷ C. Cupak, P. Szabo, H. Biber, R. Stadlmayr, C. Grave, M. Fellinger, J. Brötzner, R. Wilhelm, W. Möller, A. Mutzke, M. Moro, and F. Aumayr, Appl. Surf. Sci. 570, 151204 (2021).
³⁸ H. Knoops, E. Langereis, M. van de Sanden, and W. Kessels, J. Electrochem. Soc. 157, G241 (2010).
³⁹ V. Miikkulainen, M. Leskelä, M. Ritala, and R. Puurunen, J. Appl. Phys. 113, 021301 (2013).
40. https://plasma.oxinst.com/products/ald/flexal-ald,

### REFERENCES FOR SECTIONS 2-4

[1] T. Faraz, H. C. Knoops, M. A. Verheijen, C. A. Van Helvoirt, S. Karwal, A. Sharma, V. Beladiya, A. Szeghalmi, D. M. Hausmann, J. Henri, and M. Creatore. Tuning material properties of oxides and nitrides by substrate biasing during plasma-enhanced atomic layer deposition on planar and 3 d substrate topographies. ACS Appl. Mater. Interfaces, 10 (15): 13158-13180, 2018.
[2] K. S. A. Butcher. Hollow cathode plasma sources for plasma enhanced ald and pecvd: Properties and advantages. 2018.
[3] X. Krylov, X. Xu, K. Weinfeld, V. Korchnoy, D. Ritter, and M. Eizenberg. Properties of conductive nitride films prepared by plasma enhanced atomic layer deposition using quartz and sapphire plasma sources. Journal of Vacuum Science Technology A, 37 (1), 2019.
[4] H. G. Leduc, B. Bumble, P. K. Day, B. H. Eom, J. Gao, S. Golwala, B. A. Mazin, S. McHugh, A. Merrill, D. C. Moore, and O. Noroozian. Appl. Phys. Lett., 97:101101, 2010.
[5] Eurofins EAG laboratories. Website: https://www.eurofins.com/electronics/eag-laboratories/.
[6] Covalent metrology. Website: https://covalentmetrology.com/.
[7] B. E. Deal and A. S. Grove. General relationship for the thermal oxidation of silicon. Journal of Applied Physics, 36 (12): 3770-3778, 1965.
[8] Oxide thickness calculator. Integrated Microfabrication Lab (cleanroom). Accessed on Mar. 11, 2024.
[9] Sidewall smoothing of bosch scallops via thermal oxidation. Accessed on Mar. 12, 2024.
[10] Laserod technologies, LLC. Website: https://laserod.com/.
[11] H. C. M. Knoops, E. Langereis, M. C. M. Van De Sanden, and W. M. M. Kessels. Conformality of plasmaassisted ald: physical processes and modeling. Journal of The Electrochemical Society, 157 (12): G241, 2010.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of depositing a transition nitride film, comprising:
depositing the film on a substrate using plasma enhanced atomic layer deposition, comprising:
performing a number of deposition cycles in an atmosphere comprising no hydrogen or less than 1% hydrogen, the deposition cycles each comprising:
a precursor cycle exposing a substrate to a precursor to form a precursor treated substrate;
a plasma cycle exposing the precursor treated substrate to a plasma; and
applying an RF bias to the substrate during a portion of the plasma cycle to accelerate ions in the plasma onto the substrate; and
so that a film comprising a transition metal nitride is made.

2. The method of claim 1, wherein the precursor comprises:
tetrakis (dimethylamide) titanium (TDMAT) for the film comprising titanium nitride, or
(tert-butylimido)tris(diethylamido)niobium(V) (TBTDEN) or (tert-butylimido) tris(methylethylamido)niobium(V) (TBTMEN) for the film comprising NbN, or
Tetrakis(ethylmethylamido) vanadium for the film comprising VN, or
a chloride or fluoride of titanium,
a chloride or fluoride of vanadium, or
a chloride or fluoride of niobium.

3. The method of claim 1, wherein the transition metal nitride comprises TiN, NbN, NbTiN, VN or alloys thereof.

4. The method of claim 1, wherein the number of cycles is repeated until the film has a thickness in a range of 40-200 nm or a bulk thickness.

5. The method of claim 1, wherein the precursor cycle has duration less than 1 second, the plasma cycle has a duration of at least 20 seconds, and the RF bias is applied for at last the last 10 seconds of the plasma half cycle.

6. The method of claim 1, wherein the plasma consists of argon ions in a nitrogen atmosphere.

7. The method of claim 1, further comprising performing the deposition cycles using a pressure in the reaction chamber less than 0.1 Torr for the precursor cycle and less than 0.01 Torr for the plasma cycle.

8. The method of claim 1, wherein the substrate comprises:
three dimensional (3D) structures having an aspect ratio of at least 40, the film is deposited conformally on the 3D structures, and the substrate is float zone silicon with less than 10 particles having a diameter greater than 0.3 microns, and/or
a via having an aspect ratio selected such that the transition metal nitride deposited in the via has the crystal quality characterized by a critical temperature of 1.9K-20K.

9. The method of claim 1, further comprising selecting an angle of incidence or angular distribution of the ions on the substrate that increases a crystalline quality of the film and increases a critical temperature, for transitioning to a superconducting state, to no less than 2 Kelvin (K) or in a range or 1.9 K-20K.

10. The method of claim 9, wherein the superconducting properties are characterized by the film of thickness 100 nm or less having the critical temperature of no less than 5 K or no less than 1.9 K or in range of 1.9K-20 K.

11. The method of claim 1, wherein:
the film is deposited on a substrate comprising trenches, the method further comprising:
performing a laser ablation and laser cleaving of the film along edges and lips of the trenches to ensure that superconducting properties of the transition metal nitride are extracted within the trenches while bypassing lower-resistance planar regions of the transition metal nitride, or
using laser trimming to isolate different regions of a semiconductor or superconductor device comprising two dimensional and/or three dimensional structures.

12. The method of claim 1, further comprising performing a preconditioning step comprising at least 10 repeats of a cycle comprising a precursor exposure and a plasma exposure.

13. An apparatus for performing plasma enhanced atomic layer deposition, comprising:
a reaction chamber comprising a precursor inlet; a plasma inlet; and an outlet;
a substrate table for supporting a substrate in the reaction chamber;
a precursor source coupled to the precursor inlet for inputting a precursor to the substrate table;
a plasma source coupled to the reaction chamber and configured for forming a plasma comprising argon ions in a nitrogen atmosphere;
a gas source for supplying a hydrogen free background gas into the reaction chamber;
a pump coupled to the outlet for reducing pressure in the reaction chamber;
an RF bias source coupled to the substrate table for biasing a substrate with an RF bias; and
a computer coupled to the precursor source, the RF bias source, the pump, and the plasma source, the computer configured to instruct the apparatus to perform a number of deposition cycles each comprising:
a precursor cycle exposing the substrate to the precursor;
a plasma cycle exposing the precursor treated substrate to the plasma; and
applying the RF bias to the substrate during a portion of the plasma cycle.

14. A device comprising:
titanium nitride film deposited by atomic layer deposition and exhibiting properties as characterized by:
a resistivity and a thickness varying by less than 2% over an entirety of an area of the film; and
superconductivity at a critical temperature of no less than 5 Kelvin, no less than 1.9K, or in a range of 1.9K-20 K over an entirety of the area of the film having a thickness less than 200 nm; or
an interconnect between a first metallization on a first surface of a substrate, a second metallization on a second surface of the substrate; and a via comprising a third metallization through the substrate connecting the first metallization to the second metallization, wherein:
the via comprises a sidewall that is inclined with respect to a vertical direction through the substrate;
the third metallization comprises a thickness of 100 nm or less of transition metal nitride deposited on the sidewall, the transition metal nitride having a critical temperature of no less than 2 K or no less than 1.9K or in a range of 1.9K-20 K; and
the first metallization, the second metallization, and the third metallization consist of or comprise the transition metal nitride.

15. The device of claim 14, comprising the film on a substrate wherein the area is greater than or equal to a circular area having a diameter of at least 6 inches.

16. The device of claim 14 comprising the film having the thickness in a range of 40-100 nm and/or the film has the resistivity ρ above 70 μΩ*cm.

17. The device of claim 14, wherein the film is conformal to a surface of a substrate having an aspect ratio of at least 40 and a critical temperature of no less than 2K or no less than 1.9K or in a range of 1.9K-20 K.

18. The device of claim 14 comprising the interconnect between a first metallization on a first surface of a substrate, a second metallization on a second surface of the substrate; and a via comprising a third metallization through the substrate connecting the first metallization to the second metallization, wherein:
the via comprises a sidewall that is inclined with respect to a vertical direction through the substrate;
the third metallization comprises a thickness of 100 nm or less of transition metal nitride deposited on the sidewall, the transition metal nitride having a critical temperature of no less than 2 K or no less than 1.9K or in a range of 1.9K-20 K; and
the first metallization, the second metallization, and the third metallization consist of or comprise the transition metal nitride.

19. The device of claim 18, wherein the via has an aspect ratio, resulting in a different area of a top opening of the via as compared to an area of the base opening of the via, selected such that the transition metal nitride has the crystal quality characterized by a critical temperature of 1.9K-20K.

20. The device of claim 18, comprising a superconducting resonator, a quantum circuit, a qubit, a microwave kinetic inductance detector (MKIDs), a kinetic inductance parametric amplifiers (KIPAs), or superconducting nanowire single photon detectors (SNSPDs).
